(19) United States
(12) Patent Application Publication
(10) Pub. No.: US 2024/0404108 A1
(43) Pub. Date: Dec. 5, 2024

(54) METHODS, SYSTEMS, APPARATUS, AND ARTICLES OF MANUFACTURE FOR CAMERA CALIBRATION

(71) Applicant: Deere & Company, Moline, IL (US)

(72) Inventors: Tucker J. Schoff, Des Moines, IA (US); Ashraf Qadir, Ankeny, IA (US)

(21) Appl. No.: 18/590,550

(22) Filed: Feb. 28, 2024

Related U.S. Application Data
(60) Provisional application No. 63/506,296, filed on Jun. 5, 2023.

(51) Int. Cl. G06T 7/80; G06F 30/15

(52) U.S. Cl. CPC G06T 7/80; G06F 30/15; G06T 2207/10028

(57) ABSTRACT

Methods, systems, apparatus, and articles of manufacture for camera calibration are disclosed. An example apparatus includes memory, instructions, and programmable circuitry to execute the instructions to detect, based on video frames captured by a camera positioned on a vehicle, a ground plane of the vehicle, determine, based on the ground plane, a first position parameter of the camera with respect to a coordinate system of the vehicle, track a plurality of features between ones of the video frames, and determine, based on the plurality of features, a second position parameter of the camera with respect to the coordinate system of the vehicle, the first position parameter different from the second position parameter.

### RELATED APPLICATION

This patent claims the benefit of U.S. Provisional Patent Application No. 63/506,296, which was filed on Jun. 5, 2023. U.S. Provisional Patent Application No. 63/506,296 is hereby incorporated herein by reference in its entirety. Priority to U.S. Provisional Patent Application No. 63/506,296 is hereby claimed.

### FIELD OF THE DISCLOSURE

This disclosure relates generally to image processing and, more particularly, to methods, systems, apparatus, and articles of manufacture for camera calibration.

### BACKGROUND

Agricultural vehicles have become increasingly automated. Agricultural vehicles may semi-autonomously or fully-autonomously drive and perform operations on fields using implements for planting, spraying, harvesting, fertilizing, stripping/tilling, etc. These autonomous agricultural vehicles include multiple sensors (e.g., Global Navigation Satellite Systems (GNSS), Global Positioning Systems (GPS), Light Detection and Ranging (LIDAR), Radio Detection and Ranging (RADAR), Sound Navigation and Ranging (SONAR), telematics sensors, etc.) to help navigate without assistance, or with limited assistance, from human users. Further, agricultural vehicles typically include one or more cameras (e.g., stereoscopic cameras) to capture video frames of a surrounding environment of the agricultural vehicles. The video frames can be used to navigate and/or control one or more operations of the agricultural vehicles.

### BRIEF DESCRIPTION OF THE DRAWINGS

FIG. 1 illustrates an example vehicle including an example camera positioned thereon, where the vehicle implements example camera calibration circuitry in accordance with teachings of this disclosure.

FIG. 2 is a block diagram of an example implementation of the example camera calibration circuitry of FIG. 1.

FIG. 3 illustrates an example image captured by a first example camera for use in detecting a ground plane in a scene surrounding the example vehicle of FIG. 1.

FIG. 4A is a first example plot of an example ground plane fit to a subset of points in an example region of the image of FIG. 3.

FIG. 4B is a second example plot of the example ground plane after transformation of a first example camera coordinate system.

FIG. 5A illustrates a first example image representative of a scene surrounding the example vehicle of FIG. 1, where the first image includes example camera-shifted point pairs representing positions of features in a first camera frame and a second camera frame.

FIG. 5B illustrates a second example image representative of the scene in the first example image of FIG. 5A, where the second image includes example time-shifted point pairs representing changes in positions of features from a first time to a second time.

FIG. 6A illustrates an example graph representing first example point cloud data corresponding to the first time and second example point cloud data corresponding to the second time.

FIG. 6B illustrates a second example graph representing the first example point cloud and the first camera coordinate system after transformation.

FIG. 7 illustrates an example plot including an example camera path of the first example camera.

FIG. 8 is a flowchart representative of example machine readable instructions and/or example operations that may be executed, instantiated, and/or performed by example programmable circuitry to implement the camera calibration circuitry of FIG. 2.

FIG. 9 is a flowchart representative of example machine readable instructions and/or example operations 900 that may be executed, instantiated, and/or performed by programmable circuitry to determine an example roll angle, an example pitch angle, and/or an example roll angle in connection with block 808 of FIG. 8.

FIG. 10 is a flowchart representative of example machine readable instructions and/or example operations 1000 that may be executed, instantiated, and/or performed by programmable circuitry to determine an example yaw angle in connection with block 816 of FIG. 8.

FIG. 11 is a block diagram of an example processing platform including programmable circuitry structured to execute, instantiate, and/or perform the example machine readable instructions and/or perform the example operations of FIGS. 8, 9, and/or 10 to implement the camera calibration circuitry 102 of FIG. 2.

FIG. 12 is a block diagram of an example implementation of the programmable circuitry of FIG. 11.

FIG. 13 is a block diagram of another example implementation of the programmable circuitry of FIG. 11.

FIG. 14 is a block diagram of an example software/firmware/instructions distribution platform (e.g., one or more servers) to distribute software, instructions, and/or firmware (e.g., corresponding to the example machine readable instructions of FIGS. 8, 9, and/or 10) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Automation of vehicles (e.g., agricultural vehicles) is commercially desirable because automation can improve the accuracy with which operations are performed, reduce operator fatigue, improve efficiency, and accrue other benefits. Some vehicles include one or more cameras (e.g., stereoscopic cameras) to capture one or more video frames (e.g., image data) corresponding to surroundings and/or a projected path of the vehicle. The video frames can be processed and used to identify information about the surroundings of the vehicle. In some instances, a control system of the vehicle can utilize the information from the video frames to navigate the vehicle and/or perform one or more operations (e.g., planting, tilling, spraying, etc.) of the vehicle.

In some cases, information determined based on the video frames may be presented relative to a camera coordinate system of the camera instead of a vehicle coordinate system of the vehicle. In some instances, a camera coordinate system of the camera may be different from a vehicle coordinate system of the vehicle. Thus, the camera may need to be calibrated with respect to the vehicle coordinate system such that data corresponding to the video frames can be mapped to the vehicle coordinate system. Typically, the calibration is performed at least once during the life of the vehicle (e.g., during installation of the camera on the vehicle). In some instances, calibration is performed by positioning one or more markers (e.g., fiducial markers) in an environment of the vehicle, where actual positions of the markers are known relative to the vehicle. In such cases, the camera captures one or more images of the environment including the markers, and the positions of the markers are detected based on the captured image(s). In some examples, calibration parameters (e.g., yaw angle, pitch angle, roll angle, x-axis translation, y-axis translation, and/or z-axis translation of the camera relative to the vehicle coordinate system) are determined based on differences between the actual positions and the detected positions of the markers.

Examples disclosed herein perform calibration of a camera without the use of fiducial markers. In examples disclosed herein, the camera captures one or more first example video frames (e.g., first images) when a vehicle is stationary and/or parked on a substantially flat surface. In such examples, example camera calibration circuitry determines, based on a plurality of features detected in the first video frame(s), a ground plane on which the vehicle is positioned. In some examples, the camera calibration circuitry determines, based on the ground plane, at least one of an example roll angle, an example pitch angle, or an example z-axis coordinate of the camera with respect to an example coordinate system of the vehicle. Additionally, examples disclosed herein track features between second example video frames captured by the camera when the vehicle is moving (e.g., travelling forward along a substantially straight path). In such examples, the camera calibration circuitry determines, based on the tracked features, a yaw angle of the camera with respect to the coordinate system of the vehicle. In some examples, the camera calibration circuitry determines, based on a computer model of the vehicle, at least one of an example x-axis coordinate or a y-axis coordinate of the camera with respect to the coordinate system of the vehicle.

Examples disclosed herein detect features (e.g., rocks, protrusions, edges, etc.) in an environment of the vehicle based on images captured by a camera while the vehicle is stationary and/or moving, and calibrate the camera based on the detected features. Advantageously, examples disclosed herein can perform camera calibration without the use of fiducial markers, where such fiducial markers can introduce inaccuracies in the calibration due to improper placement of the markers. Further, examples disclosed herein separate a calibration process into a first procedure (e.g., a plane fitting procedure) for determining first calibration parameter(s) (e.g., roll angle, pitch angle, and/or z-axis coordinate) and a second procedure (e.g., a feature tracking procedure) for determining second calibration parameter(s) (e.g., yaw angle). By separating the calibration process into multiple procedures, examples disclosed herein can reduce and/or distribute a computational load required to perform the calibration.

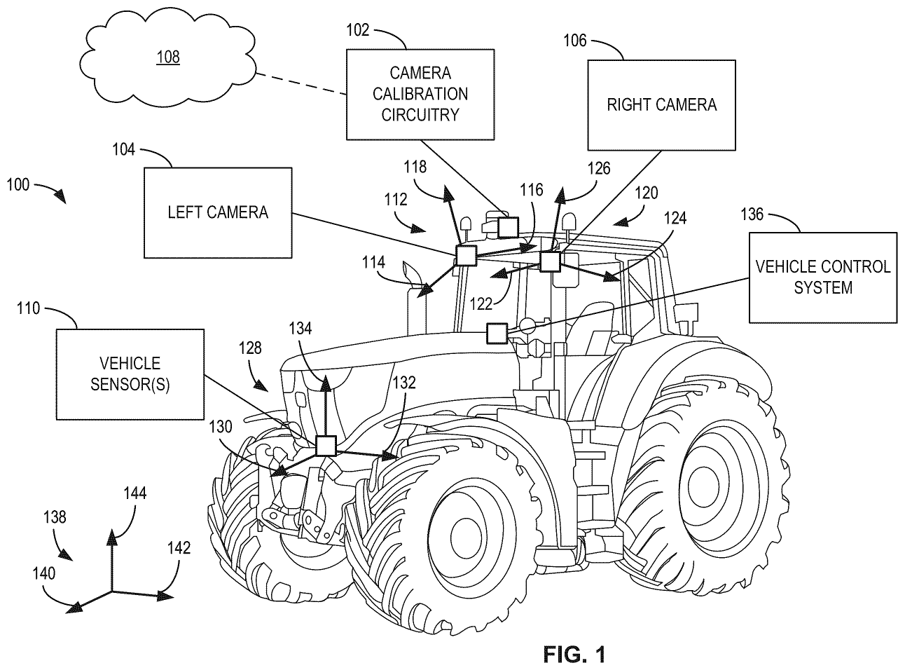

FIG. 1 illustrates an example vehicle 100 implementing example camera calibration circuitry 102 in accordance with teachings of this disclosure. In the illustrated example of FIG. 1, the vehicle 100 is an agricultural vehicle (e.g., a tractor). However, the vehicle 100 can be any type of vehicle (e.g., a tractor, front loader, harvester, cultivator, or any other suitable vehicle). In this example, a first example camera (e.g., a left camera, a first stereo camera) 104 and a second example camera (e.g., a right camera, a second stereo camera) 106 are implemented on the vehicle 100. In some examples, the cameras 104, 106 are stereoscopic cameras that capture image data corresponding to an environment and/or a projected path of the vehicle 100. For example, each of the cameras 104, 106 corresponds to a stereo pair including at least two camera sensors (e.g., a first camera sensor and a second camera sensor) that capture images from two different perspectives and/or viewpoints. In this example, the cameras 104, 106 are communicatively coupled to the camera calibration circuitry 102 to provide the captured image data thereto. In some examples, the camera calibration circuitry 102 is communicatively coupled to an example network 108. In this example, the camera calibration circuitry 102 is implemented locally at the vehicle 100 to determine calibration information for the cameras 104, 106. In some examples, the camera calibration circuitry 102 can be implemented remotely (e.g., in a cloud-based environment, on another vehicle and/or device, etc.), and the camera calibration circuitry 102 provides the calibration information to the vehicle 100 via the network 108.

In the example of FIG. 1, the vehicle 100 includes one or more example vehicle sensors 110 to measure and/or obtain vehicle data corresponding to the vehicle 100. For example, the vehicle sensors 110 can include a position sensor (e.g., a global positioning sensor (GPS)) to detect a geographic position of the vehicle 100. Additionally or alternatively, the vehicle sensors 110 can include one or more inertial sensors (e.g., accelerometers, gyroscopes, etc.) to measure acceleration, velocity, and/or orientation (e.g., yaw, pitch, and/or roll) of the vehicle 100. In some examples, the camera calibration circuitry 102 obtains and/or stores the vehicle data from the vehicle sensors 110 for use in calibrating the cameras 104, 106.

In the example of FIG. 1, an orientation and/or position of the first camera 104 is represented by a first example camera coordinate system 112 of the first camera 104. In this example, the first camera coordinate system 112 includes a first example camera x-axis 114, a first example camera y-axis 116, and a first example camera z-axis 118 having an origin at a location of the first camera 104. Further, an orientation and/or position of the second camera 106 is represented by a second example camera coordinate system 120 of the second camera 106. In this example, the second camera coordinate system 120 includes a second example camera x-axis 122, a second example camera y-axis 124, and a second example camera z-axis 126 having an origin at a location of the second camera 106. In this example, an orientation and/or position of the vehicle 100 is determined relative to an example vehicle coordinate system 128. The vehicle coordinate system 128 includes an example vehicle x-axis 130, an example vehicle y-axis 132, and an example vehicle z-axis 134.

In some examples, the vehicle 100 includes an example vehicle control system 136 to control one or more operations of the vehicle 100. For example, the vehicle control system 136 can control steering and/or acceleration of the vehicle 100, raising and/or lowering of an implement attached to the vehicle 100, etc. In some examples, the vehicle control system 136 controls the one or more operations based on positions of objects relative to the vehicle coordinate system 128 of the vehicle 100. In some examples, to detect the positions of the objects in an environment of the vehicle 100, the vehicle control system 136 utilizes images captured by the first camera 104 and/or the second camera 106. However, in some examples, the objects in the captured images are represented relative to the respective first and second camera coordinate systems 112, 120 instead of the vehicle coordinate system 128 of the vehicle 100. In some examples, to enable mapping of the positions of the objects from the first and second camera coordinate systems 112, 120 to the vehicle coordinate system 128, the camera calibration circuitry 102 determines positions and/or orientations of the first and second camera coordinate systems 112, 120 relative to the vehicle coordinate system 128.

In the illustrated example of FIG. 1, the camera calibration circuitry 102 calibrates the first and second cameras 104, 106 by determining a transformation (e.g., rotation and/or translation) between the camera coordinate systems 112, 120 and the vehicle coordinate system 128. For example, the camera calibration circuitry 102 determines, relative to the vehicle coordinate system 128, at least one of an x-axis coordinate, a y-axis coordinate, a z-axis coordinate, a yaw angle, a roll angle, or a pitch angle of at least one of the first camera coordinate system 112 or the second camera coordinate system 120. Additionally or alternatively, the camera calibration circuitry 102 determines a transformation between the vehicle coordinate system 128 and an example world coordinate system (e.g., a world frame, a reference coordinate system) 138 of an environment of the vehicle 100, where the world coordinate system 138 includes an example world x-axis 140, an example world y-axis 142, and an example world z-axis 144.

In some examples, the camera calibration circuitry 102 performs the calibration based on images captured by the cameras 104, 106 and/or based on vehicle data (e.g., GPS data, computer aided design (CAD) models) provided to and/or stored in the camera calibration circuitry 102. For example, the first camera 104 captures one or more first images representative of a scene relative to the first camera coordinate system 112, and the second camera 106 captures one or more second images representative of the scene relative to the second camera coordinate system 120. In some examples, the camera calibration circuitry 102 processes, using one or more image processing techniques, the first and second images to identify features represented therein. For example, the features correspond to objects (e.g., rocks, protrusions, etc.), textures, and/or colors in the scene represented in the first and second images.

In some examples, the camera calibration circuitry 102 determines two-dimensional (2D) positions (e.g., pixel coordinates) of the first and second features relative to respective image coordinate systems of the first and second images. In some such examples, based on the 2D positions of the first and second features, the camera calibration circuitry 102 determines at least one of the yaw angle, the pitch angle, the roll angle, or the z-axis coordinate of the first camera coordinate system 112 and/or the second camera coordinate system 120 relative to the vehicle coordinate system 128. Further, in some examples, the camera calibration circuitry 102 determines at least one of the x-axis coordinate or the y-axis coordinate of the first camera coordinate system 112 and/or the second camera coordinate system 120 relative to the vehicle coordinate system 128 based on a CAD model of the vehicle 100.

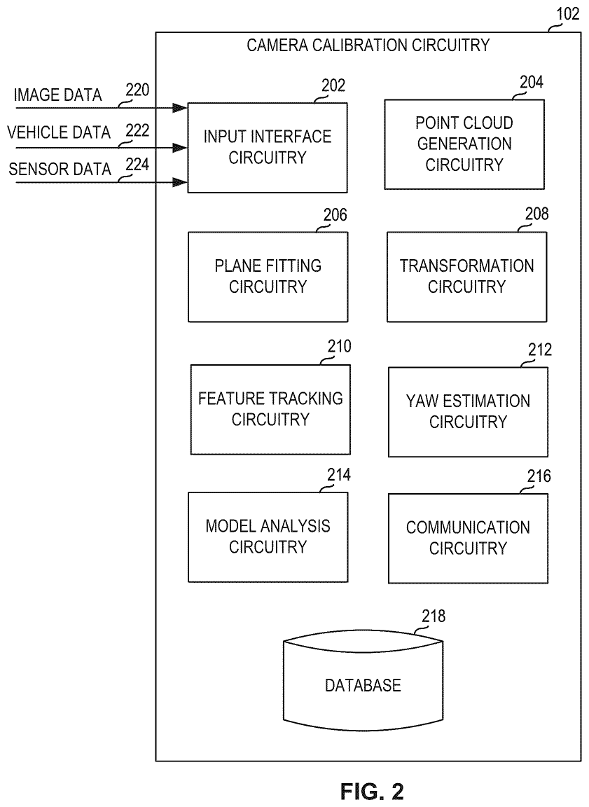

FIG. 2 is a block diagram of an example implementation of the camera calibration circuitry 102 of FIG. 1. The camera calibration circuitry 102 of FIG. 2 may be instantiated (e.g., creating an instance of, bring into being for any length of time, materialize, implement, etc.) by programmable circuitry such as a Central Processor Unit (CPU) executing first instructions. Additionally or alternatively, the camera calibration circuitry 102 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

In the illustrated example of FIG. 2, the example camera calibration circuitry 102 includes example input interface circuitry 202, example point cloud generation circuitry 204, example plane fitting circuitry 206, example transformation circuitry 208, example feature tracking circuitry 210, example yaw estimation circuitry 212, example model analysis circuitry 214, example communication circuitry 216, and an example database 218.

The example database 218 stores data utilized and/or obtained by the camera calibration circuitry 102. The example database 218 of FIG. 2 is implemented by any memory, storage device and/or storage disc for storing data such as, for example, flash memory, magnetic media, optical media, solid state memory, hard drive(s), thumb drive(s), etc. Furthermore, the data stored in the example database 218 may be in any data format such as, for example, binary data, comma delimited data, tab delimited data, structured query language (SQL) structures, etc. While, in the illustrated example, the example database 218 is illustrated as a single device, the example database 218 and/or any other data storage devices described herein may be implemented by any number and/or type(s) of memories.

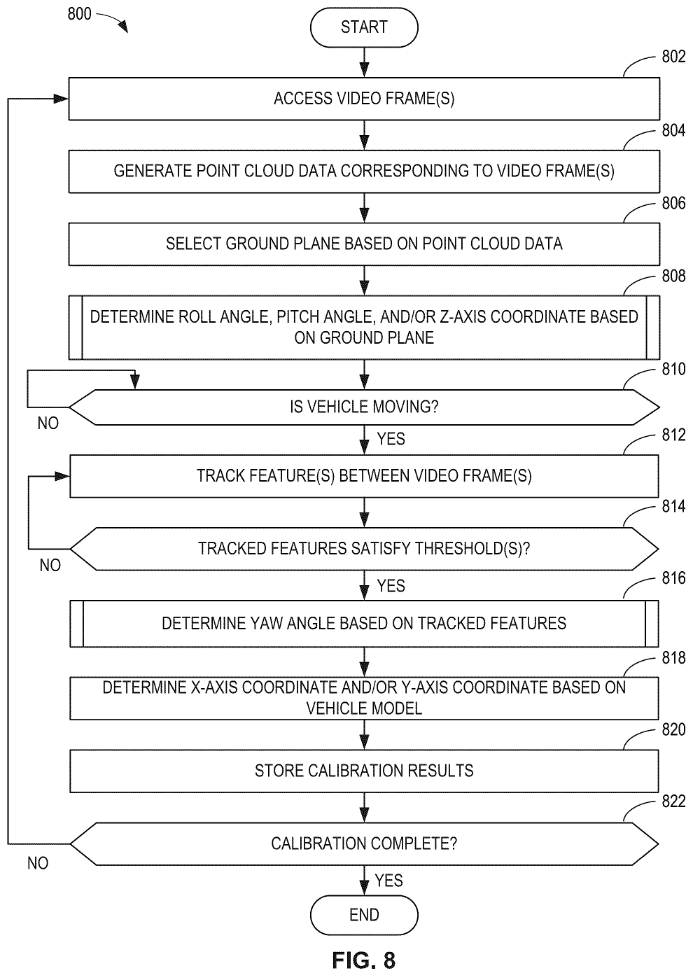

The example input interface circuitry 202 of FIG. 2 obtains and/or accesses input data from the example vehicle sensors 110 and/or the example vehicle control system 136 of FIG. 1. For example, the input interface circuitry 202 obtains example image data 220 from the first example camera 104 and/or the second example camera 106 of FIG. 1. In some examples, the image data 220 includes one or more first images (e.g., first video frames) captured by a first camera sensor of the first camera 104, one or more second images (e.g., second video frames) captured by a second camera sensor of the first camera 104, one or more third images (e.g., third video frames) captured by a third camera sensor of the second camera 106, and/or one or more fourth images (e.g., fourth video frames) captured by a fourth camera sensor of the second camera 106. In some examples, the input interface circuitry 202 obtains example vehicle data 222 from the example vehicle control system 136 of FIG. 1 and/or from the example network 108 of FIG. 1. In some examples, the vehicle data 222 includes an example computer aided design (CAD) model of the vehicle 100. In some examples, the input interface circuitry 202 obtains example sensor data 224 from the example vehicle sensors 110 implemented on the example vehicle 100 of FIG. 1. In some examples, the sensor data 224 includes GPS data representing a location of the vehicle coordinate system 128. In some examples, the input interface circuitry 202 provides the image data 220, the vehicle data 222, and/or the sensor data 224 to the database 218 for storage therein. In some examples, the input interface circuitry 202 is instantiated by programmable circuitry executing input interface instructions and/or configured to perform operations such as those represented by the flowchart(s) of FIG. 8.

The example point cloud generation circuitry 204 generates and/or obtains point cloud data corresponding to one(s) of the first and second images and/or one(s) of the third and fourth images included in the image data 220. As used herein, point cloud data refers to a set of discrete data points in a 3D space. In some examples, the point cloud data generated and/or obtained by the point cloud generation circuitry 204 corresponds to points in a 3D scene represented in the first and second images and/or in the third and fourth images. A calibration process for calibrating the first camera 104 based on the first and second images is described below. In some examples, the calibration process can similarly be used to calibrate the second camera 106 based on the third and fourth images.

In some examples, to generate the point cloud data, the point cloud generation circuitry 204 determines a disparity image (e.g., a disparity map, a depth map) based on corresponding ones of the first and second images. For example, the point cloud generation circuitry 204 selects a first one of the first images and a second one of the second images corresponding to approximately a same time (e.g., captured by the respective first and second camera sensors of the first camera 104 at approximately the same time). In such examples, the first one of the first images and the second one of the second images represent a same 3D scene surrounding the vehicle 100, but from different viewpoints corresponding to different viewpoints of the first and second camera sensors of the first camera 104. In some examples, the point cloud generation circuitry 204 matches first 2D points (e.g., first pixels) in the first one of the first images with corresponding second 2D points (e.g., second pixels) in the second one of the second images. In such examples, the first 2D points and the respective second 2D points correspond to same locations (e.g., the same 3D points) in the 3D scene.

Further, the point cloud generation circuitry 204 determines first pixel coordinates of the first 2D points relative to a first camera frame of the first camera sensor, and determines second pixel coordinates of the second 2D points relative to a second camera frame of the second camera sensor. In some examples, the point cloud generation circuitry 204 determines distances (e.g., 2D distances) between corresponding ones of the first and second 2D points mapped onto a same camera frame (e.g., the first camera frame of the first camera sensor or the second camera frame of the second camera sensor). In some examples, the point cloud generation circuitry 204 estimates, based on the distances between the first and second 2D points, depth values for the corresponding 3D points in the 3D scene. For example, the depth values can be inversely proportional to the corresponding distances. In some examples, the depth values represent distances (e.g., 3D distances) from a focal point of one of the first camera sensor or the second camera sensor to the corresponding 3D points.

In some examples, the point cloud generation circuitry 204 generates the disparity image based on the depth values and one of the first image or the second image. For example, the disparity image corresponds to the one of the first image or the second image, where the depth values of the 3D points are represented by intensities (e.g., brightness) of the corresponding 2D points. In some examples, the intensities of the first 2D points are proportional to the corresponding depth values. For example, points that are further from the one of the first camera sensor or the second camera sensor (e.g., have a greater depth value) can be brighter compared to points that are closer to the one of the first camera sensor or the second camera sensor (e.g., have a lower depth value). Conversely, in some examples, points that are further from the one of the first camera sensor or the second camera sensor are less bright compared to points that are closer to the one of the first camera sensor or the second camera sensor.

In some examples, the point cloud generation circuitry 204 determines the point cloud data based on the disparity image. For example, the point cloud generation circuitry 204 executes one or more image processing algorithms to output the point cloud data based on the disparity image. For example, the disparity image indicates differences in pixel positions of objects represented in two images of a stereo pair (e.g., the first and second camera sensors of the first camera 104). In some examples, an object that is far away from the first camera 104 has substantially no difference in pixel position, while an object that is close to the first camera 104 has a relatively large difference in pixel position and, thus, a relatively large disparity value. In some examples, the point cloud generation circuitry 204 determines the point cloud data based on the disparity image and one or more parameters of the first camera 104. For example, the parameters can include focal lengths of the first and second camera sensors of the first camera 104, principal points of the first and second camera sensors of the first camera 104, and/or a physical distance between the first and second camera sensors of the first camera 104. In some examples, the point cloud generation circuitry 204 performs geometric calculations based on the parameters and the disparity values from the disparity image to determine a point cloud location for one(s) of the pixels in images from the first and second camera sensors.

In some examples, the point cloud data includes 3D coordinates (e.g., x-axis coordinates, y-axis coordinates, and z-axis coordinates) of one or more points relative to the first camera coordinate system 112 of the first camera 104. In some examples, the one or more points correspond to a ground on which the vehicle 100 of FIG. 1 is positioned. While the point cloud generation circuitry 204 determines the point cloud data based on images from the first camera 104 in this example, the point cloud generation circuitry 204 can determine the point cloud data based on the sensor data 224 from one or more of the vehicle sensors 110 of FIG. 1 (e.g., data from a LiDAR sensor of the vehicle 100) in some examples. In some examples, the point cloud generation circuitry 204 is instantiated by programmable circuitry executing point cloud generation instructions and/or configured to perform operations such as those represented by the flowchart(s) of FIG. 8.

In the illustrated example of FIG. 2, the example plane fitting circuitry 206 of FIG. 2 determines, based on the point cloud data, a ground plane of the ground on which the vehicle 100 is positioned. Further, based on the ground plane, the plane fitting circuitry 206 can determine at least one of an example roll angle, an example pitch angle, and/or an example z-axis coordinate of the first camera coordinate system 112 relative to the vehicle coordinate system 128 of FIG. 1.

In some examples, the plane fitting circuitry 206 utilizes a random sample consensus (RANSAC) algorithm to determine an example ground plane based on the point cloud data. For example, the plane fitting circuitry 206 selects a subset of data points from the point cloud data, where the data points correspond to a region of one of the images captured by the first camera 104. In some examples, the subset includes at least three of the data points from the point cloud data. In some examples, the plane fitting circuitry 206 iteratively selects a candidate ground plane and calculates an error value for the candidate ground plane based on distances between the candidate ground plane and the subset of data points. In some examples, in response to determining that the error value of the candidate ground plane satisfies an example error threshold, the plane fitting circuitry 206 selects the candidate ground plane as the ground plane for the vehicle 100. In some examples, in response to determining that the error value does not satisfy the error threshold, the plane fitting circuitry 206 iteratively selects different candidate ground planes until a corresponding error value of the candidate ground planes satisfies the error threshold. In some examples, the plane fitting circuitry 206 determines the ground plane as a vector normal to the ground plane. For example, the plane fitting circuitry 206 determines a first ground plane vector, denoted by ¹n, representing a first ground plane normal relative to the first camera sensor of the first camera 104, and determines a second ground plane vector, denoted by ²n, representing the ground plane normal relative to the second camera sensor of the first camera 104. In some examples, the plane fitting circuitry 206 is instantiated by programmable circuitry executing plane fitting instructions and/or configured to perform operations such as those represented by the flowchart(s) of FIG. 8.

In some examples, the example transformation circuitry 208 determines a transformation (e.g., a relative rotation and/or translation) between the first camera sensor and the second camera sensor based on the first and second ground plane vectors. For example, the transformation circuitry 208 determines an example rotation matrix ¹R₂ and an example translation vector ¹t₂ to transform a second coordinate system of the second camera sensor to a first coordinate system of the first camera sensor, such that a center of the first camera sensor corresponds to an origin of the first coordinate system and the second coordinate system. Additionally or alternatively, in some examples, the transformation circuitry 208 selects a center of the second camera sensor as the origin of the first and second coordinate systems, such that an inverse of the rotation matrix and the translation vector can be used to transform the first coordinate system to the second coordinate system.

To determine the transformation between the first and second coordinate systems, the transformation circuitry 208 relates the first ground plane normal of the first camera sensor to the second ground plane normal of the second camera sensor based on the rotation matrix as shown in example Equation 1 below.

$${}^{1} n = {}^{1} {R}_{2} {}^{2} n \qquad ( Equation 1 )$$

In example Equation 1 above, ¹n represents the first ground plane normal of the first camera sensor, ²n represents the second ground plane normal of the second camera sensor, and ¹R₂ represents the rotation matrix between the first and second coordinate systems of the respective first and second camera sensors. In some examples, based on an example plane equation ax+by+cz=d, the transformation circuitry 208 determines a first example plane equation for the first coordinate system as shown in example Equation 2 below.

$${1}^{} {n}^{T} {}^{1} X = {}^{1} d \qquad ( Equation 2 )$$

In example Equation 2 above, ¹X represents x-axis, y-axis, and z-axis coordinates of a point in the first coordinate system, ¹n^{T} represents a transpose of the first ground plane normal of the first camera sensor, and ¹d represents a distance between the origin of the first coordinate system and the point corresponding to ¹X. In some examples, based on example Equation 2 above, the transformation circuitry 208 generates example Equation 3 below.

$${}^{1} X = {}^{1} {R}_{2} {}^{2} X + {}^{1} {t}_{2} \qquad ( Equation 3 )$$

In example Equation 3 above, ²X represents x-axis, y-axis, and z-axis coordinates of the second coordinate system of the second camera sensor. In some examples, example Equation 3 above can be used to map (e.g., transform) a second point represented by ²X in the second coordinate system to a first point represented by ¹X in the first coordinate system. For example, the first point in the first coordinate system can be determined by determining a product of the rotation matrix (e.g., ¹R₂) and the second point in the second coordinate system, then determining a sum of the product and the translation vector (e.g., ¹t₂).

In some examples, example Equation 2 above can be rewritten by transposing a left hand side and a right hand side of Equation 2 and rearranging variables in the left and right hand sides to generate example Equation 4 below.

$${}^{1} {R}_{2} {}^{2} n = {}^{1} n \qquad ( Equation 4 )$$

$${⇒ {(}^{1} {R}_{2} {}^{2} n )}^{T} = {}^{1} {n}^{T}$$

$$⇒ {}^{2} {n}^{T} {( {}^{1} {R}_{2} )}^{T} = {}^{1} {n}^{T}$$

$$⇒ {}^{2} {n}^{T} = {}^{1} {n}^{T} {}^{1} {R}_{2}$$

In example Equation 4 above, a transpose of the second ground plane normal (e.g., ²n^{T}) in the second coordinate system corresponds to a product of the rotation matrix (e.g., ¹R₂) and a transpose of the first ground plane normal (e.g., ¹n^{T}) in the first coordinate system. In some examples, the transformation circuitry 208 generates example Equation 5 below by substituting example Equation 3 above into example Equation 2 above.

$${}^{1} {n}^{T} {(}^{1} {R}_{2} {}^{2} X + {}^{1} {t}_{2} ) = {}^{1} d = {}^{2} {n}^{T} {}^{2} X + {}^{1} {n}^{T} {}^{1} {t}_{2} \qquad ( Equation 5 )$$

$$⇒ {}^{1} {n}^{T} {}^{1} {t}_{2} + {}^{2} d - {}^{1} d = 0$$

In example Equation 5 above, a right hand side corresponds to zero, and the transformation circuitry 208 determines a left hand side of Equation 5 above by determining a product of the transpose of the first ground plane normal (e.g., ¹n^{T}) and the translation vector (e.g., ¹t₂), determining a sum of the product and a second distance (e.g., ²d) in the second coordinate system, then subtracting a first distance (e.g., 1^{d}) in the first coordinate system from the sum. In such examples, the first distance corresponds to a first radial distance between an origin of the first coordinate system and a first point in the first coordinate system (e.g., represented by ¹X), and the second distance corresponds to a second radial distance between an origin of the second coordinate system and a corresponding second point in the second coordinate system (e.g., represented by ²X).

In some examples, the transformation circuitry 208 determines a cost function based on example Equations 1 and 5 above, where the cost function is represented in example Equation 6 below.

$${arg min}_{r ∈ {ℜ}^{3} , t ∈ {ℜ}^{3}} {\sum }_{i = 1}^{N} {‖ {}^{1} {n}_{i} - R {}^{2} {n}_{i} ‖}^{2} + {\sum }_{i = 1}^{N} {‖ {}^{1} {n}_{i}^{T} {}^{1} {t}_{2} + {}^{2} {d}_{i} - {}^{1} {d}_{i} ‖}^{2} \qquad ( Equation 6 )$$

In example Equation 6 above, N represents a number of plane-to-plane correspondences between the first and second coordinate systems of the respective first and second camera sensors. In some examples, the transformation circuitry 208 determines values for the rotation matrix (e.g., ¹R₂) and the translation vector (e.g., ¹t₂) based on example Equation 6 above. For example, the transformation circuitry 208 iteratively selects candidate values for the rotation matrix and the translation vector, and calculates an error based on Equation 6 above. In some examples, when the error corresponding to the selected candidate values satisfies an error threshold, the transformation circuitry 208 selects the candidate values as the determined values for the rotation matrix and the translation vector. In some examples, the transformation circuitry 208 stores the rotation matrix and the translation vector in the example database 218.

In some examples, based on the rotation matrix and the translation vector, the transformation circuitry 208 can map (e.g., convert, transform) points and/or features in the second coordinate system of the second camera sensor to corresponding points and/or features in the first coordinate system of the first camera sensor. Further, in some examples, the transformation circuitry 208 determines an example vehicle-to-camera rotation matrix (e.g., ^{C}R_{S}) to enable mapping of points and/or features in the first camera coordinate system 112 to corresponding points and/or features in the example vehicle coordinate system 128 of FIG. 1.

In some examples, to determine the vehicle-to-camera rotation matrix, the transformation circuitry 208 determines an example vehicle-to-world rotation matrix (e.g., ^{W}R_{S}) based on the example sensor data 224. For example, the sensor data 224 includes measurement data from an example inertial navigation system (INS) and/or an example inertial measurement unit (IMU) of the vehicle 100, where the measurement data indicates an example vehicle-to-world roll angle and/or an example vehicle-to-world pitch angle of the vehicle coordinate system 128 relative to the example world coordinate system 138 of FIG. 1. Further, the transformation circuitry 208 determines the example vehicle z-axis 134 corresponds to the example world z-axis 144 of FIG. 1, such that an example yaw angle between the vehicle coordinate system 128 and the world frame is approximately zero. In some examples, the transformation circuitry 208 generates the example vehicle-to-world rotation matrix (e.g., ^{W}R_{S}) based on the roll angle, the pitch angle, and the yaw angle of the vehicle coordinate system 120 relative to the world coordinate system 138.

In some examples, when the vehicle 100 is positioned on the ground and the ground is substantially flat (e.g., substantially parallel to a reference plane defined by the world x-axis 140 and the world y-axis 142 of the world coordinate system 138), the vehicle z-axis 134 of FIG. 1 corresponds to the ground plane normal relative to the vehicle coordinate system 128 (e.g., ^{S}n). Stated differently, the ground plane normal in the vehicle coordinate system 128 can be represented as ^{S}n=[0 0 1]^{T}. In some examples, based on the ground plane normal in the vehicle coordinate system 128 (e.g., ^{S}n) and the vehicle-to-world rotation matrix (e.g., ^{W}R_{S}), the ground plane normal in the world coordinate system 138 (e.g., ^{W}n) can be represented as shown in example Equation 7 below.

$${}^{W} n = {}^{W} {R}_{S} {}^{S} n \qquad ( Equation 7 )$$

In example Equation 7 above, ^{W}n represents the ground plane normal in the world coordinate system 138, and ^{W}n corresponds to a product of the vehicle-to-world rotation matrix (e.g., ^{W}R_{S}) and the ground plane normal in the vehicle coordinate system 128 (e.g., ^{S}n). As such, the transformation circuitry 208 can transform the ground plane normal in the vehicle coordinate system 128 (e.g., ^{S}n) to the ground plane normal in the world coordinate system 138 (e.g., ^{W}n) using example Equation 7 above. Similarly, in some examples, the transformation circuitry 208 determines a transformation between the ground plane normal in the first camera coordinate system 112 (e.g., denoted by ^{C}n) and the ground plane normal in the world coordinate system 138 (e.g., ^{W}n) based on example Equation 8 below.

$${}^{W} n = {}^{W} {R}_{C} {}^{C} n \qquad ( Equation 8 )$$

In example Equation 8 above, the ground plane normal in the world coordinate system 138 (e.g., ^{W}n) corresponds to a product of the ground plane normal in the first camera coordinate system 112 (e.g., ^{C}n) and an example camera-to-world rotation matrix (e.g., ^{W}R_{C}). In some examples, the transformation circuitry 208 generates example Equation 9 below by equating example Equations 7 and 8 above.

$${}^{W} n = {}^{W} {R}_{S} {}^{S} n = {}^{W} {R}_{C} {}^{C} n \qquad ( Equation 9 )$$

$$⇒ {( {}^{W} {R}_{C} )}^{- 1} ( {}^{W} {R}_{S} ) {}^{S} n = {}^{C} n$$

$$⇒ {}^{C} {R}_{W} {}^{W} {R}_{S} {}^{S} n = {}^{C} n$$

$$⇒ {}^{C} {R}_{S} {}^{S} n - {}^{C} n$$

$$⇒ {}^{C} {R}_{S} {}^{S} n - {}^{C} n = 0$$

In example Equation 9 above, ^{S}R_{C} represents an example camera-to-vehicle rotation matrix for use in determining a rotation of the vehicle coordinate system 128 relative to the first camera coordinate system 112 of FIG. 1. In some examples, the transformation circuitry 208 determines, based on example Equation 9 above, an example cost function as shown in example Equation 10 below.

$${arg min}_{r ∈ {ℜ}^{2} ( ϕ , θ )} = {\sum }_{i = 1}^{N} {‖ {}^{C} {{R}_{S}}^{S} {n}_{i} {-}^{C} {n}_{i} ‖}^{2} \qquad ( Equation 10 )$$

In example Equation 10 above, N represents a number of plane-to-plane correspondences between the first and second coordinate systems. In some examples, the transformation circuitry 208 determines values for an example vehicle-to-camera rotation matrix (e.g., ^{C}R_{S}) based on example Equation 10 above. For example, the transformation circuitry 208 iteratively selects candidate values for the vehicle-to-camera rotation matrix and calculates an error based on Equation 10 above. In some examples, when the error corresponding to the selected candidate values satisfies an error threshold, the transformation circuitry 208 selects the candidate values as the determined values for the vehicle-to-camera rotation matrix. In some examples, the transformation circuitry 208 stores the vehicle-to-camera rotation matrix in the example database 218.

In some examples, based on the vehicle-to-camera rotation matrix, the transformation circuitry 208 determines an example roll angle and/or an example pitch angle of the first camera coordinate system 112 relative to the vehicle coordinate system 128. For example, the roll angle and the pitch angle indicate angles of rotation of the first camera coordinate system 112 about the first camera x-axis 114 and the first camera y-axis 116, respectively, to align the first ground plane normal with the first camera z-axis 118 of the first camera coordinate system 112. Further, in some examples, the transformation circuitry 208 determines, based on the ground plane normal, an example z-axis coordinate of the first camera coordinate system 112 relative to the vehicle coordinate system 128. For example, the z-axis coordinate corresponds to a distance (e.g., a height), along the ground plane normal, from the ground plane to an origin of the first camera coordinate system 112. In some examples, the transformation circuitry 208 obtains the z-axis coordinate directly from the plane equation of the ground plane normal, where the plane equation indicates the distance to the ground plane calculated based on the point cloud data. In some examples, the transformation circuitry 208 is instantiated by programmable circuitry executing transformation instructions and/or configured to perform operations such as those represented by the flowchart(s) of FIGS. 8 and/or 9.

In the illustrated example of FIG. 2, the example feature tracking circuitry 210 detects and/or tracks example features in example video frames of the image data 220, where the video frames correspond to different times. In this examples, the video frames include first example video frames captured by the first camera sensor of the first camera 104 and/or second example video frames captured by the second camera sensor of the first camera 104. In some examples, the features correspond to objects (e.g., rocks, protrusions, edges, etc.) and/or textures in the scene represented in the video frames. In some examples, the feature tracking circuitry 210 executes one or more image processing algorithms and/or one or more neural network models based on the video frames to detect the features therein. In some examples, the feature tracking circuitry 210 detects at least a threshold number (e.g., three, ten, etc.) of features in one(s) of the video frames.

In the example of FIG. 2, the feature tracking circuitry 210 detects first features in a first video frame of the first video frames and second features in a second video frame of the second video frames, where the first video frame and the second video frame correspond to a same point in time (e.g., a first time). In such examples, the feature tracking circuitry 210 determines first pixel positions of the first features in the first video frame and second pixel positions of the second features in the second video frame. In some such examples, the feature tracking circuitry 210 matches (e.g., maps) one(s) of the first features with corresponding one(s) of the second features. Further, based on the transformation (e.g., rotation and/or translation) between the first and second camera sensors determined by the transformation circuitry 208 and based on a comparison of the first and second pixel positions for the matched features, the feature tracking circuitry 210 determines three-dimensional positions of the matched features in the first camera coordinate system 112 at the first time.

In some examples, the feature tracking circuitry 210 determines changes in the three-dimensional positions of matched features between ones of the first video frames and/or between one(s) of the second video frames corresponding to different times. For example, the feature tracking circuitry 210 determines first three-dimensional positions of the matched features in first ones of the video frames (e.g., the first and second video frames) corresponding to the first time and determines second three-dimensional positions of the matched features in second ones of the video frames corresponding to a second time (e.g., after the first time). In such examples, the feature tracking circuitry 210 determines changes in the three-dimensional positions over time, and estimates trajectories of the matched features based on the changes in the three-dimensional positions.

In some examples, the feature tracking circuitry 210 generates, for a given time, example point cloud data based on the three-dimensional positions of the features at the given time. For example, the feature tracking circuitry 210 generates first point cloud data based on the first three-dimensional positions at the first time and generates second point cloud data based on the second three-dimensional positions at the second time. In some examples, the feature tracking circuitry 210 causes storage of the point cloud data in the example database 218. In some examples, the feature tracking circuitry 210 is instantiated by programmable circuitry executing feature tracking instructions and/or configured to perform operations such as those represented by the flowchart(s) of FIG. 8.

In the illustrated example of FIG. 2, the example yaw estimation circuitry 212 estimates, based on the point cloud data generated by the feature tracking circuitry 210, an example yaw angle of the first camera coordinate system 112 relative to the vehicle coordinate system 128. For example, the yaw estimation circuitry 212 estimates the yaw angle based on a comparison between a camera path (e.g., a camera trajectory) of the first camera 104 and a vehicle path (e.g., a vehicle trajectory) of the vehicle 100. In such examples, the yaw estimation circuitry 212 determines the vehicle path based on GPS data from the vehicle sensor(s) 110 of FIG. 1. In some examples, the yaw estimation circuitry 212 determines the camera path based on the point cloud data from images captured by the first camera 104. In some such examples, the GPS data and the point cloud data are obtained while the vehicle 100 travels forward along a relatively straight (e.g., not curved) path.

In some examples, the yaw estimation circuitry 212 utilizes a coherent point drift algorithm to determine the camera path based on the point cloud data. For example, the yaw estimation circuitry 212 uses the coherent point cloud drift algorithm to determine a transformation that maps (e.g., align) a first point cloud onto a second point cloud, where the first and second point cloud correspond to different images captured at different points in time. In some examples, the transformation represents a change in position (e.g., rotation and/or translation) of the first camera 104 between the two images and/or the two points in time. In some examples, the yaw estimation circuitry 212 determines the transformations for subsequent pairs of images captured by the first camera 104 and determines the camera path based on a combination of the transformations across the multiple images. While a coherent point drift algorithm is used in this example, one or more different techniques (e.g. least squares regression) can be used to determine the camera path based on the point cloud data.

In some examples, the yaw estimation circuitry 212 determines the yaw angle of the camera coordinate system 112 relative to the vehicle coordinate system 128 based on a comparison of the vehicle path and the camera path. For example, the yaw estimation circuitry 212 determines the yaw angle corresponding to an angle between the camera path and the vehicle path. In some examples, the yaw estimation circuitry 212 causes storage of the yaw angle in the example database 218 of FIG. 2. In some examples, the yaw estimation circuitry 212 is instantiated by programmable circuitry executing yaw estimation instructions and/or configured to perform operations such as those represented by the flowchart(s) of FIGS. 8 and/or 10.

In the illustrated example of FIG. 2, the model analysis circuitry 214 determines an example x-axis coordinate and/or an example y-axis coordinate of the first camera coordinate system 112 relative to the vehicle coordinate system 128. For example, the model analysis circuitry 214 obtains a computer model (e.g., a computer aided design (CAD) model) representative of the vehicle 100 from the database 218. In some examples, the computer model is pre-loaded in the model analysis circuitry 214, and/or obtained from a cloud-based storage via the example network 108 of FIG. 1. In this example, the model analysis circuitry 214 determines the x-axis coordinate and/or the y-axis coordinate based on the computer model of the vehicle 100. In some examples, the model analysis circuitry 214 causes storage of the x-axis coordinate and/or the y-axis coordinate in the example database 218 of FIG. 2. In some examples, the model analysis circuitry 214 is instantiated by programmable circuitry executing model analysis instructions and/or configured to perform operations such as those represented by the flowchart(s) of FIG. 8.

In the illustrated example of FIG. 2, the example communication circuitry 216 obtains and/or sends network communications via the example network 108 of FIG. 1. For example, in response to the camera calibration circuitry 102 determining camera calibration data (e.g., the x-axis coordinate, the y-axis coordinate, the z-axis coordinate, the yaw angle, the roll angle, and/or the pitch angle) for the first camera 104 and/or the second camera 106, the communication circuitry 216 provides the calibration data to a cloud-based environment for storage and/or for transmission to another vehicle and/or computer. In some examples, the communication circuitry 216 provides the calibration data to one or more control systems of the vehicle 100, where the control system(s) utilize the image data 220 from the first camera 104 and/or the second camera 106 to control the vehicle 100. In some such examples, the control system(s) can activate one or more vehicle controls (e.g., steering of the vehicle 100, raising and/or lowering of an implement coupled to the vehicle 100, etc.) based on the image data 220 and/or the calibration data. In some examples, the communication circuitry 216 receives data (e.g., the vehicle data 222 and/or the computer model of the vehicle 100) via one or more network communications. In some examples, the communication circuitry 216 is instantiated by programmable circuitry executing communication instructions and/or configured to perform operations such as those represented by the flowchart(s) of FIG. 8.

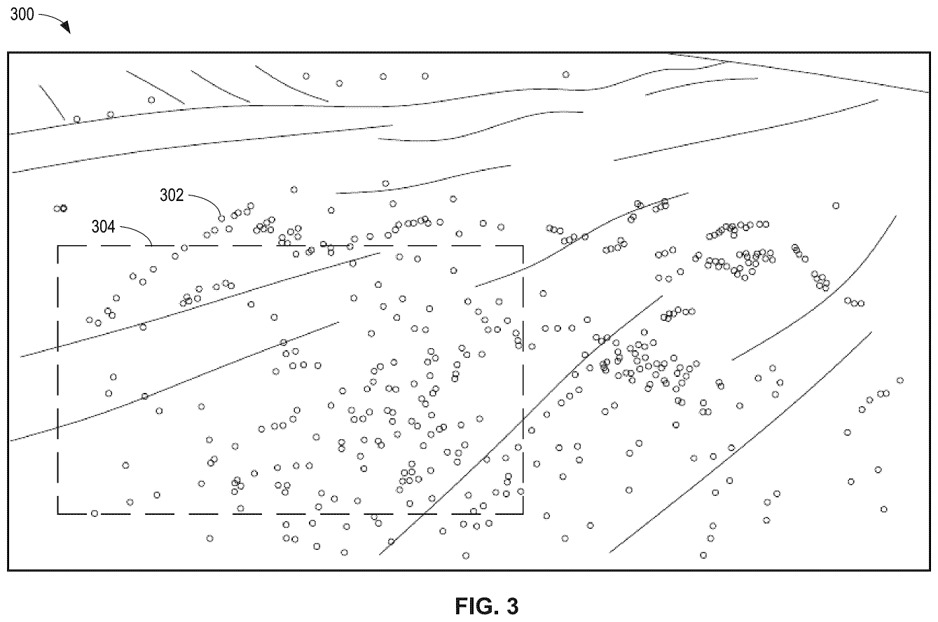

FIG. 3 illustrates an example image 300 captured by the first camera 104 for use in detecting a ground plane in a 3-D scene surrounding the example vehicle 100 of FIG. 1. In some examples, the example point cloud generation circuitry 204 of FIG. 2 generates example point cloud data corresponding to the image 300, where the point cloud data includes a plurality of example points 302 in the image 300 corresponding to locations (e.g., 3-D locations) of features detected in the environment of the vehicle 100. In the example of FIG. 3, the example plane fitting circuitry 206 of FIG. 2 selects an example region (e.g., a region of interest) 304 of the image 300 for use in ground plane fitting. For example, the region 304 includes a subset of the points 302 of the point cloud data. In some examples, the region 304 is manually selected. In some examples, the region 304 corresponds to a portion of the image 300 which provides an unobstructed view of the ground. In some examples, the plane fitting circuitry 206 does not select the region 304 and performs ground plane fitting using a different portion (e.g., all) of the points 302 of the point cloud data.

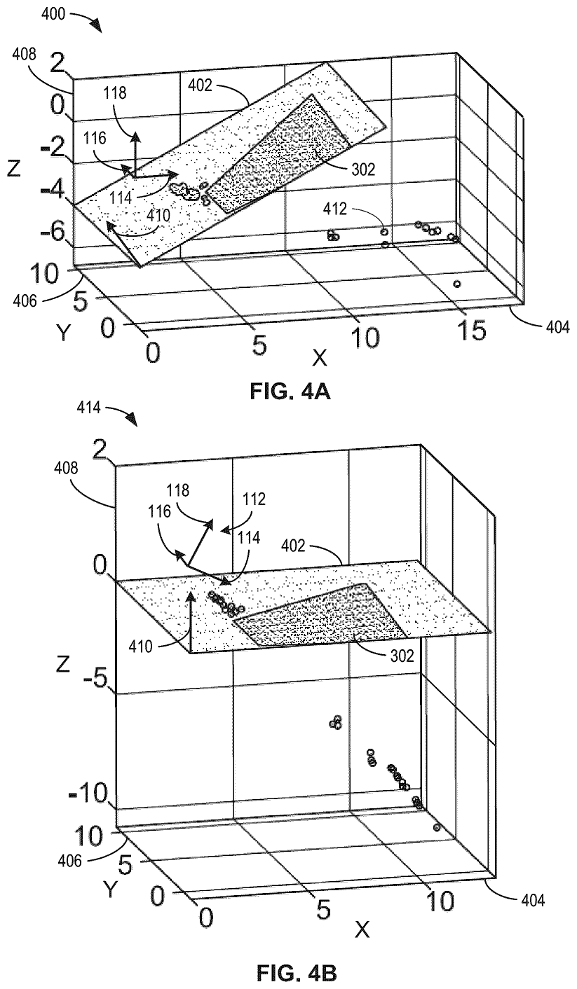

FIG. 4A is a first example plot (e.g., a 3-D plot) 400 of an example ground plane 402 fit to the subset of the example points 302 in the example region 304 of FIG. 3. In the illustrated example of FIG. 4A, the first plot 400 represents the points 302 plotted relative to the first example camera coordinate system 112 of FIG. 1. For example, the first plot 400 includes a first example axis (e.g., an x-axis) 404 corresponding to (e.g., substantially aligned with) the first camera x-axis 114, a second example axis (e.g., a y-axis) 406 corresponding to the first camera y-axis 116, and a third example axis (e.g., a z-axis) 408 corresponding to the first camera z-axis 118. In this example, first, second, and third axes 404, 406, 408 correspond to units of meters. In some examples, different units can be used for one or more of the first, second, and third axes 404, 406, 408.

In the illustrated example of FIG. 4A, the example plane fitting circuitry 206 of FIG. 2 plots the subset of the points 302 relative to the first, second, and third axes 404, 406, 408. In some examples, the plane fitting circuitry 206 executes a RANSAC algorithm based on the subset of the points 302 to determine the ground plane 402. For example, the plane fitting circuitry 206 iteratively selects a candidate ground plane and calculates an error value for the candidate ground plane based on distances between the candidate ground plane and the subset of the points 302. In this example, the plane fitting circuitry 206 selects the ground plane 402 of FIG. 4A in response to the error value of the ground plane 402 satisfying a threshold. In some examples, the plane fitting circuitry 206 determines an example ground plane normal 410 corresponding to a vector that is normal (e.g., orthogonal) to the ground plane 402.

In this example, the plane fitting circuitry 206 utilizes a RANSAC algorithm to fit the ground plane 402 to the subset of the points 302. In some examples, the RANSAC algorithm enables selection of the ground plane 402 while ignoring and/or reducing an effect of example outlier points 412 (e.g., ones of the points 302 that are not within a threshold distance of the ground plane 402). While a RANSAC algorithm is used for the selection of the ground plane 402 in this example, a different technique (e.g., least squares regression) can be used to select the ground plane 402 instead.

FIG. 4B is a second example plot 414 of the ground plane 402 after transformation of the first example camera coordinate system 112 relative to the first, second, and third axes 404, 406, 408 of FIG. 4A. In the illustrated example of FIG. 4B, the example transformation circuitry 208 of FIG. 2 determines the transformation (e.g., rotation and/or translation) of the first camera coordinate system 112 and/or the ground plane 402 relative to the first, second, and third axes 404, 406, 408 that results in the ground plane vector 410 corresponding to (e.g., being substantially aligned with) the third axis 408. In some examples, the transformation circuitry 208 determines the transformation based on the ground plane vector 410 and the example cost function represented in example Equations 7-10 above.

In some examples, as a result of determining the transformation, the transformation circuitry 208 determines a first angle of rotation about the first axis 404 (e.g., a roll angle), a second angle of rotation about the second axis 406 (e.g., a pitch angle), and/or a translation along the third axis 408 (e.g., a z-axis translation, a z-axis coordinate) of the first camera coordinate system 112 to align the ground plane vector 410 with the third axis 408. In the example of FIG. 4B, the transformation circuitry 208 determines that the first camera coordinate system 112 of FIG. 4B, relative to the first camera coordinate system 112 shown in FIG. 4A, is rotated approximately 0.22 degrees about the first axis 404, is rotated approximately 26.84 degrees about the second axis 406 and is translated approximately 3.46 meters along the third axis 408.

In some examples, the example vehicle z-axis 134 of the example vehicle coordinate system 128 of FIG. 1 is substantially parallel to the ground plane normal 410. As such, the roll angle, the pitch angle, and the z-axis translation determined by the transformation circuitry 208 for the first camera coordinate system 112 relative to the first, second, and third axes 404, 406, 408 of FIG. 4B correspond to the roll angle, the pitch angle, and the z-axis translation of the first camera coordinate system 112 relative to the vehicle coordinate system 128. In some examples, the transformation circuitry 208 stores the determined roll angle, the pitch angle, and the z-axis translation as calibration data in the example database 218 of FIG. 2.

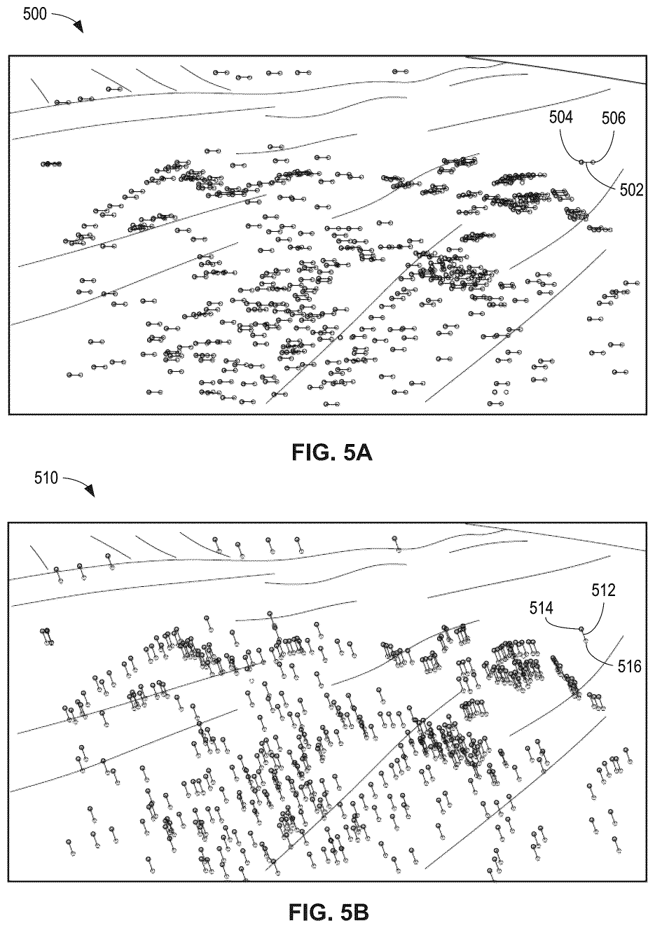

FIG. 5A illustrates a first example image 500 representative of a 3-D scene surrounding the example vehicle 100 of FIG. 1 at a given time (e.g., a first time). In the illustrated example of FIG. 5A, the first image 500 includes a plurality of example camera-shifted point pairs 502, where the camera-shifted point pairs 502 represent corresponding features in the 3-D scene. In this example, each of the camera-shifted point pairs 502 includes a first example point 504 representing a feature in a first camera frame of the first camera sensor of the first camera 104, and a second example point 506 representing the feature in a second camera frame of the second camera sensor of the first camera 104. In some examples, based on a distance between the first and second points 504, 506 and respective focal lengths of the first and second camera sensors, the example feature tracking circuitry 210 of FIG. 2 can determine, by triangulation, a 3-D position of the feature represented by the corresponding camera-shifted point pair 502. In this example, the 3-D position is represented relative to the first camera coordinate system 112. In some examples, the feature tracking circuitry 210 similarly determines the 3-D positions of the features corresponding to remaining ones of the camera-shifted point pairs 502, and generates example point cloud data for the first image 500 based on the 3-D positions.

FIG. 5B illustrates a second example image 510 representative of the 3-D scene in the first example image 500 of FIG. 5A, where the second image 510 includes example time-shifted point pairs 512 representing changes in positions of features over time (e.g., from a first time to a second time) relative to the first camera 104. In some examples, as the example vehicle 100 of FIG. 1 traverses a vehicle path, the first camera 104 captures images including one(s) of the features at different times. In some such examples, actual positions of the features (e.g., relative to the world coordinate system 138 of FIG. 1) remain the same over time, while relative positions of the features (e.g., relative to the first camera 104) may change over time.

In some examples, the second image 510 is captured by the first example camera 104 at the first time, and the example feature tracking circuitry 210 determines, based on the second image 510, first positions (e.g., first relative positions) of the features relative to the first camera frame at the first time. In this example, the first positions of the features at the first time are represented by corresponding first example points 514 of the time-shifted point pairs 512. Similarly, a third image is captured by the first camera 104 at the second time, and the feature tracking circuitry 210 determines, based on the third image, second positions (e.g., second relative positions) of the features relative to the first camera frame at the second time. In this example, the second positions of the features at the second time are represented by corresponding second example points 516 of the time-shifted point pairs 512.

In some examples, the feature tracking circuitry 210 determines, based on the first points 514, first 3-D positions of the features relative to the first camera coordinate system 112 at the first time (e.g., based on triangulation between the first and second camera sensors of the first camera 104 as described above in connection with FIG. 5A). Similarly, the feature tracking circuitry 210 determines, based on the second points 516, second 3-D positions of the features relative to the first camera coordinate system 112 at the second time. In this example, the first 3-D positions correspond to a first point cloud, and the second 3-D positions correspond to a second point cloud.

In some examples, based on the first and second point clouds, the example yaw estimation circuitry 212 of FIG. 2 determines a transformation (e.g., a rotation and/or a translation) of the first camera coordinate system 112 from the first time to the second time. In some such examples, based on the transformation, the yaw estimation circuitry 212 can determine a camera path (e.g., a camera trajectory) of the first camera 104 as the vehicle 100 travels along a path (e.g., forward along a straight line). In some examples, the yaw estimation circuitry 212 determines the transformation using a coherent point drift algorithm.

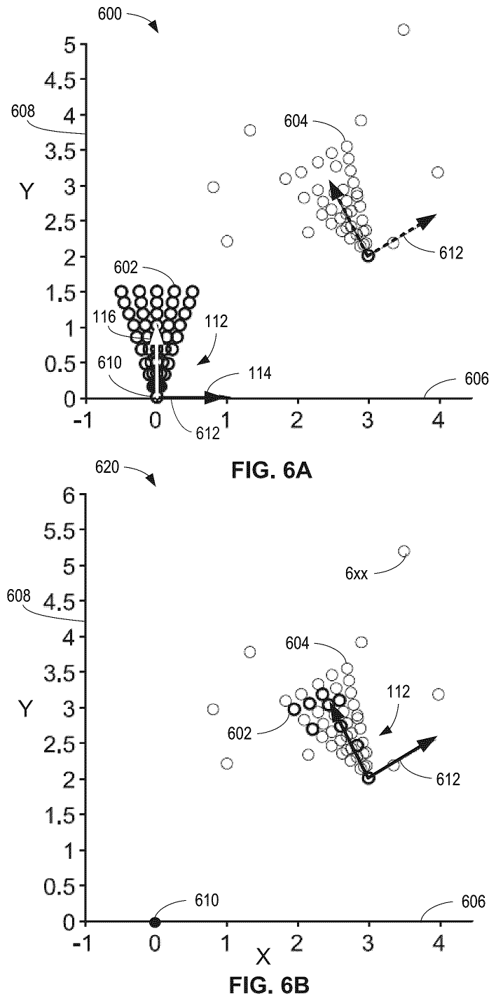

FIG. 6A illustrates an example graph 600 representing first example point cloud data 602 corresponding to the first time and second example point cloud data 604 corresponding to the second time. In the illustrated example of FIG. 6A, the graph 600 includes a first example axis (e.g., an x-axis) 606 corresponding to the first camera x-axis 114 of the first camera 104 of FIG. 1, and a second example axis (e.g., a y-axis) 608 corresponding to the first camera y-axis 116 of FIG. 1. In this example, units along the first and second axes 606, 608 correspond to meters. In some examples, different units (e.g., feet, inches, etc.) can be used instead. In this example, the first camera coordinate system 112 of the first camera 104 is positioned at a zero value (e.g., zero meters) along the first axis 606 and a zero value (e.g., zero meters) along the second axis 608.

As described above in connection with FIG. 5B, the first point cloud data 602 represents locations of features relative to the first camera coordinate system 112 at the first time, and the second point cloud data 604 represents the locations of the features relative to the first camera coordinate system 112 at the second time. In such examples, actual locations of the features (e.g., relative to the world coordinate system 138 of FIG. 1) represented in the first and second point clouds 602, 604 do not change from the first time to the second time.

In the example of FIG. 6A, the example yaw estimation circuitry 212 of FIG. 2 identifies corresponding ones of the features between the first and second point clouds 602, 604. In this example, the yaw estimation circuitry 212 determines, using a coherent point drift algorithm, a transformation that maps ones of the features represented in the first point cloud 602 to the corresponding ones of the features represented in the second point cloud 604. For example, the yaw estimation circuitry 212 determines the transformation (e.g., rotation and/or translation) along an example 2-D plane (e.g., defined by the first and second axes 606, 608) that maps the first point cloud 602 onto the second point cloud 604. In the illustrated example of FIG. 6A, the yaw estimation circuitry 212 determines that, to map the first point cloud 602 into the second point cloud 604, the first point cloud 602 is to be translated 3 meters along the first axis 606, 2 meters along the second axis 608, and rotated approximately 30 degrees clockwise along the 2-D plane (e.g., about a third example axis oriented out of the page in FIG. 6A).

In some examples, the yaw estimation circuitry 212 utilizes the transformation between the first and second point clouds 602, 604 to determine how much the first camera 104 (represented by the first camera coordinate system 112) has travelled from the first time to the second time. For example, the first camera coordinate system 112 is at a first example position (e.g., a first location and/or first orientation) 612 at the first time. In this example, the yaw estimation circuitry 212 applies the transformation to the first camera coordinate system 112 to determine a second example position (e.g., a second location and/or second orientation) 614 of the first camera coordinate system 112 at the second time. As a result of the transformation, a relative position of the second point cloud 604 to the first camera coordinate system 112 in the second position 614 approximately corresponds to a relative position of the first point cloud 602 to the first camera coordinate system 112 in the first position 612.

FIG. 6B illustrates a second example graph 620 representing the first example point cloud 602 and the first camera coordinate system 112 after transformation by the example yaw estimation circuitry 212. In this example, the first camera coordinate system 112 is in the second position 612 (e.g., translated 3 meters along the first axis 606, 2 meters along the second axis 608, and rotated approximately 30 about the third axis 610 compared to the first position 612 of FIG. 6A). In the illustrated example of FIG. 6B, the first point cloud 602 is mapped onto and/or substantially overlapping a portion of the second point cloud 604.

In this example, the second point cloud 604 includes one or more example outlier points 622 onto which the transformed first point cloud 602 does not map and/or overlap. In some examples, the outlier points 622 correspond to features that were inaccurately or incorrectly detected by the feature tracking circuitry 210 (e.g., as a result of obstructions and/or blurriness in captured images from the first camera 104). In some examples, by utilizing a coherent point drift algorithm, the yaw estimation circuitry 212 can ignore the outlier points 622 when determining the transformation between the first and second point clouds 602, 604, thus reducing error in the transformation compared to when other techniques (e.g., least squares best fit) are used. However, while a coherent point drift algorithm is used in this example, one or more different techniques for determining the transformation between the first and second point clouds 602, 604 can be used instead.

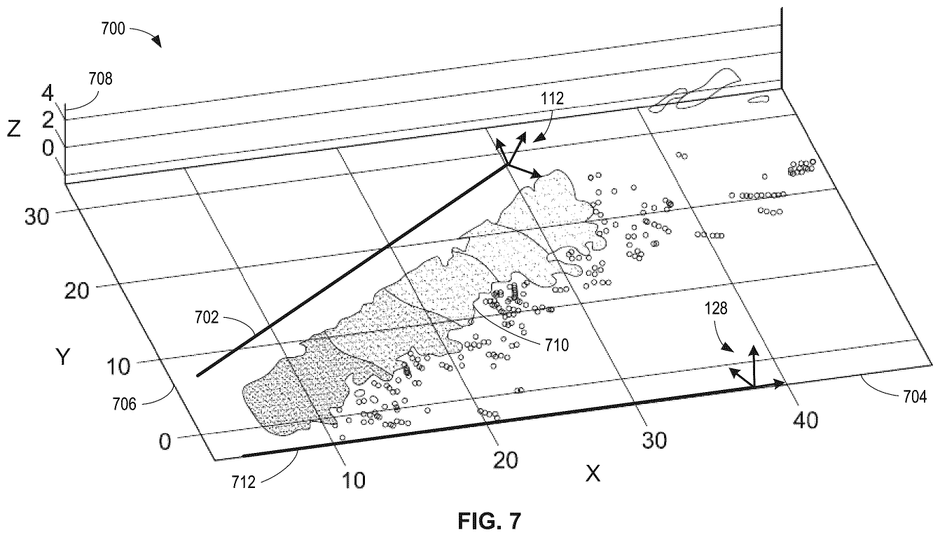

FIG. 7 illustrates an example 3-D plot 700 including an example camera path (e.g., a camera trajectory) 702 of the first example camera 104. In the illustrated example of FIG. 7, the plot 700 includes an example x-axis 704, an example y-axis 706, and an example z-axis 708 defining a 3-D space. In this example, a position and/or orientation of the first camera 104 in the 3-D space is represented by the first camera coordinate system 112.

In the illustrated example of FIG. 7, the yaw estimation circuitry 212 determines the camera path 702 based on an aggregation of transformations (e.g., rotations and/or translations) of the first camera coordinate system 112 across subsequent video frames captured by the first camera 104. For example, as discussed in connection with FIGS. 6A and 6B above, the yaw estimation circuitry 212 determines the transformations between corresponding ones of the video frames based on example point cloud data 710 generated for the ones of the video frames. In the example of FIG. 7, the point cloud data 710 includes a plurality of example point clouds (e.g., the first point cloud 602 and/or the second point cloud 604 of FIGS. 6A and/or 6B) corresponding to ones of the video frames.

In this example, the video frames are captured by the first camera 104 for a duration for which the vehicle 100 travels forward along a substantially straight path. In particular, the vehicle 100 travels along an example vehicle path (e.g., a vehicle trajectory) 712 that is substantially aligned with the x-axis 704 of FIG. 7, where a position and/or orientation of the vehicle 100 is represented by the vehicle coordinate system 128. In the example of FIG. 7, the yaw estimation circuitry 212 determines an example yaw angle between the camera path 702 and the vehicle path 712, where the yaw angle is approximately 38 degrees in this example. In this example, the yaw angle indicates an angle of rotation (e.g., about the vehicle z-axis 134) of the first camera coordinate system 112 relative to the vehicle coordinate system 128. In some examples, the yaw estimation circuitry 212 causes storage of the yaw angle as calibration data in the example database 218 of FIG. 2.

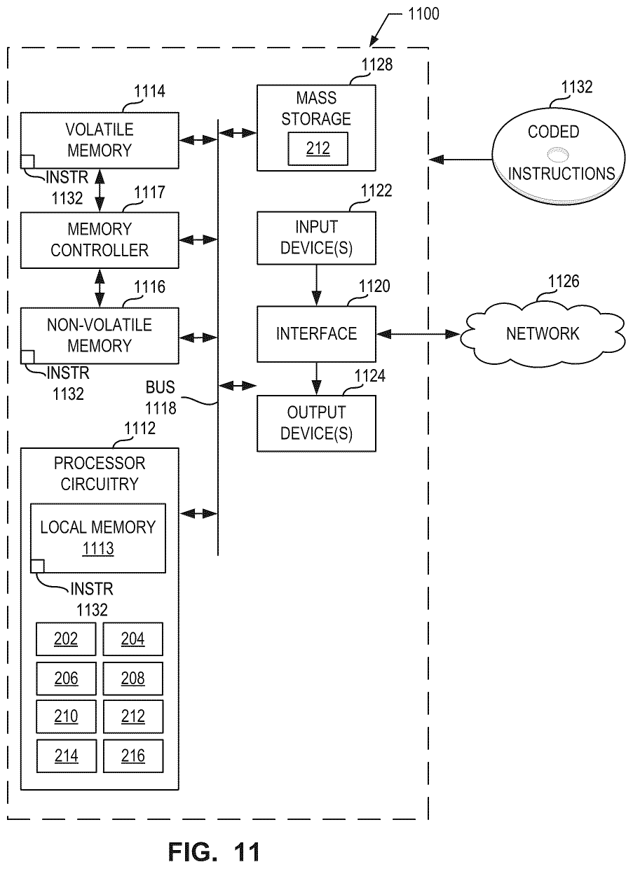

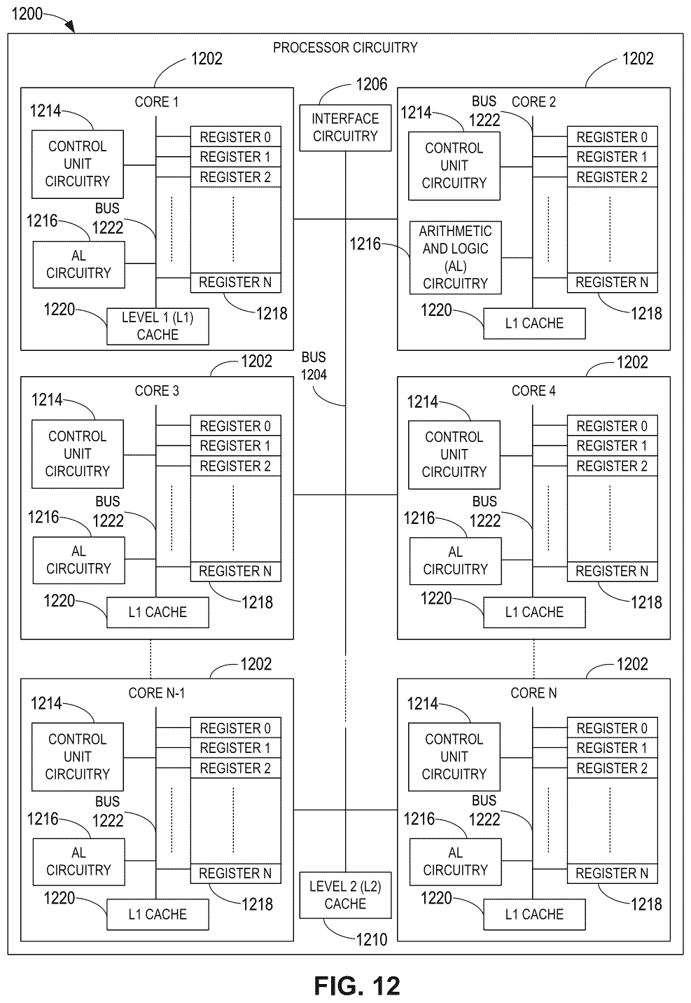

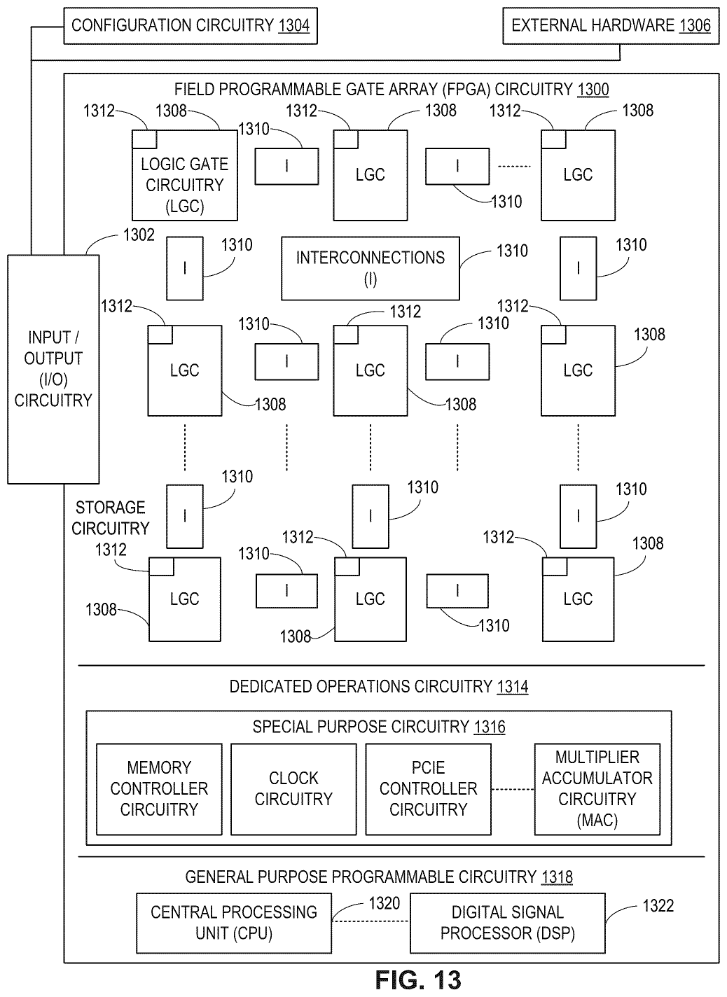

In some examples, the camera calibration circuitry 102 includes means for obtaining input. For example, the means for obtaining input may be implemented by the input interface circuitry 202. In some examples, the input interface circuitry 202 may be instantiated by programmable circuitry such as the example programmable circuitry 1112 of FIG. 11. For instance, the input interface circuitry 202 may be instantiated by the example microprocessor 1200 of FIG. 12 executing machine executable instructions such as those implemented by at least blocks 802, 804 of FIG. 8. In some examples, the input interface circuitry 202 may be instantiated by hardware logic circuitry, which may be implemented by an ASIC, XPU, or the FPGA circuitry 1300 of FIG. 13 configured and/or structured to perform operations corresponding to the machine readable instructions. Additionally or alternatively, the input interface circuitry 202 may be instantiated by any other combination of hardware, software, and/or firmware. For example, the input interface circuitry 202 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the camera calibration circuitry 102 includes means for generating point clouds. For example, the means for generating point clouds may be implemented by the point cloud generation circuitry 204. In some examples, the point cloud generation circuitry 204 may be instantiated by programmable circuitry such as the example programmable circuitry 1112 of FIG. 11. For instance, the point cloud generation circuitry 204 may be instantiated by the example microprocessor 1200 of FIG. 12 executing machine executable instructions such as those implemented by at least block 804 of FIG. 8. In some examples, the point cloud generation circuitry 204 may be instantiated by hardware logic circuitry, which may be implemented by an ASIC, XPU, or the FPGA circuitry 1300 of FIG. 13 configured and/or structured to perform operations corresponding to the machine readable instructions. Additionally or alternatively, the point cloud generation circuitry 204 may be instantiated by any other combination of hardware, software, and/or firmware. For example, the point cloud generation circuitry 204 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the camera calibration circuitry 102 includes means for selecting a ground plane. For example, the means for selecting a ground plane may be implemented by the plane fitting circuitry 206. In some examples, the plane fitting circuitry 206 may be instantiated by programmable circuitry such as the example programmable circuitry 1112 of FIG. 11. For instance, the plane fitting circuitry 206 may be instantiated by the example microprocessor 1200 of FIG. 12 executing machine executable instructions such as those implemented by at least block 806 of FIG. 8. In some examples, the plane fitting circuitry 206 may be instantiated by hardware logic circuitry, which may be implemented by an ASIC, XPU, or the FPGA circuitry 1300 of FIG. 13 configured and/or structured to perform operations corresponding to the machine readable instructions. Additionally or alternatively, the plane fitting circuitry 206 may be instantiated by any other combination of hardware, software, and/or firmware. For example, the plane fitting circuitry 206 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

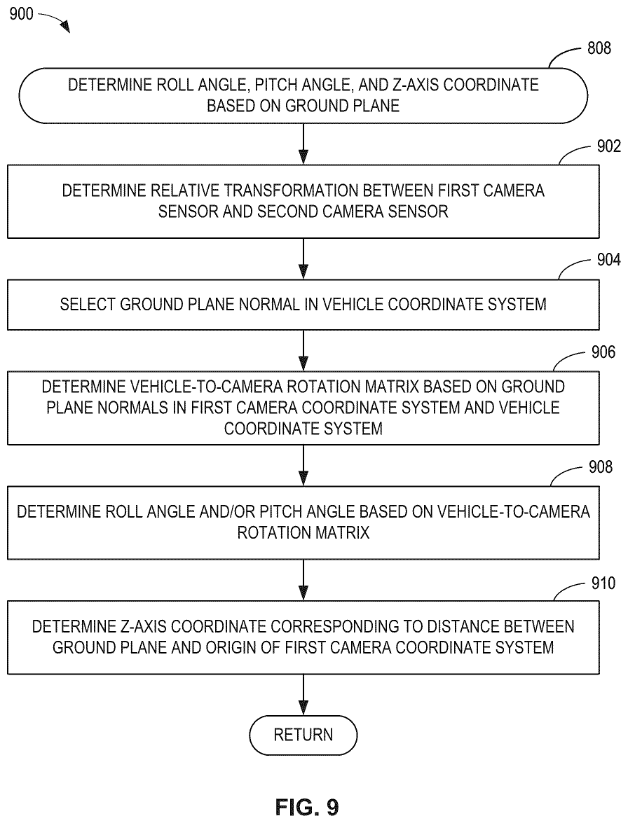

In some examples, the camera calibration circuitry 102 includes means for determining transformations. For example, the means for determining transformations may be implemented by the transformation circuitry 208. In some examples, the transformation circuitry 208 may be instantiated by programmable circuitry such as the example programmable circuitry 1112 of FIG. 11. For instance, the transformation circuitry 208 may be instantiated by the example microprocessor 1200 of FIG. 12 executing machine executable instructions such as those implemented by at least blocks 808, 820, 822 of FIG. 8 and/or blocks 902, 904, 906, 908, 910 of FIG. 9. In some examples, the transformation circuitry 208 may be instantiated by hardware logic circuitry, which may be implemented by an ASIC, XPU, or the FPGA circuitry 1300 of FIG. 13 configured and/or structured to perform operations corresponding to the machine readable instructions. Additionally or alternatively, the transformation circuitry 208 may be instantiated by any other combination of hardware, software, and/or firmware. For example, the transformation circuitry 208 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the camera calibration circuitry 102 includes means for tracking. For example, the means for tracking may be implemented by the feature tracking circuitry 210. In some examples, the feature tracking circuitry 210 may be instantiated by programmable circuitry such as the example programmable circuitry 1112 of FIG. 11. For instance, the feature tracking circuitry 210 may be instantiated by the example microprocessor 1200 of FIG. 12 executing machine executable instructions such as those implemented by at least blocks 812, 814 of FIG. 8. In some examples, the feature tracking circuitry 210 may be instantiated by hardware logic circuitry, which may be implemented by an ASIC, XPU, or the FPGA circuitry 1300 of FIG. 13 configured and/or structured to perform operations corresponding to the machine readable instructions. Additionally or alternatively, the feature tracking circuitry 210 may be instantiated by any other combination of hardware, software, and/or firmware. For example, the feature tracking circuitry 210 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

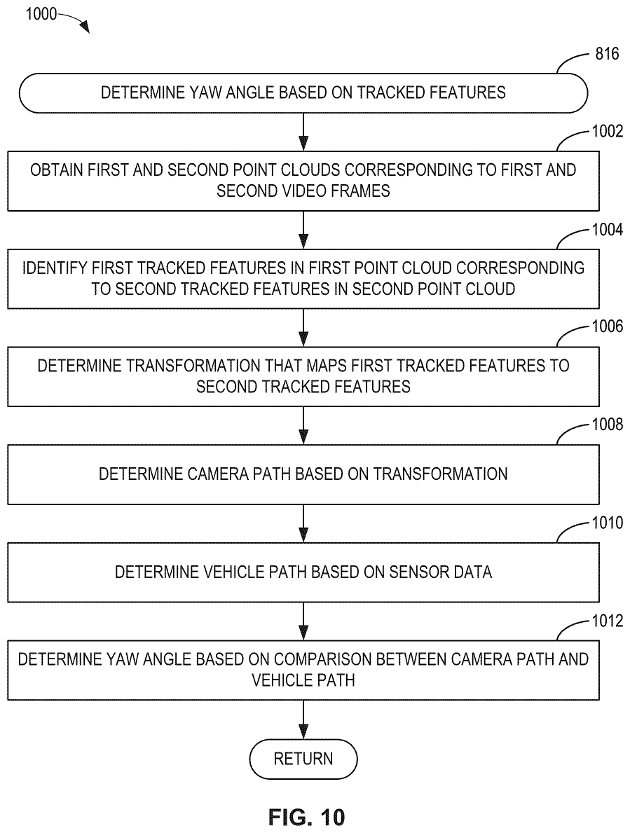

In some examples, the camera calibration circuitry 102 includes means for estimating a yaw angle. For example, the means for estimating a yaw angle may be implemented by the yaw estimation circuitry 212. In some examples, the yaw estimation circuitry 212 may be instantiated by programmable circuitry such as the example programmable circuitry 1112 of FIG. 11. For instance, the yaw estimation circuitry 212 may be instantiated by the example microprocessor 1200 of FIG. 12 executing machine executable instructions such as those implemented by at least blocks 816, 820, 822 of FIG. 8 and/or blocks 1002, 1004, 1006, 1008, 1010, 1012 of FIG. 10. In some examples, the yaw estimation circuitry 212 may be instantiated by hardware logic circuitry, which may be implemented by an ASIC, XPU, or the FPGA circuitry 1300 of FIG. 13 configured and/or structured to perform operations corresponding to the machine readable instructions. Additionally or alternatively, the yaw estimation circuitry 212 may be instantiated by any other combination of hardware, software, and/or firmware. For example, the yaw estimation circuitry 212 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the camera calibration circuitry 102 includes means for analyzing. For example, the means for analyzing may be implemented by the model analysis circuitry 214. In some examples, the model analysis circuitry 214 may be instantiated by programmable circuitry such as the example programmable circuitry 1112 of FIG. 11. For instance, the model analysis circuitry 214 may be instantiated by the example microprocessor 1200 of FIG. 12 executing machine executable instructions such as those implemented by at least block 818 of FIG. 8. In some examples, the model analysis circuitry 214 may be instantiated by hardware logic circuitry, which may be implemented by an ASIC, XPU, or the FPGA circuitry 1300 of FIG. 13 configured and/or structured to perform operations corresponding to the machine readable instructions. Additionally or alternatively, the model analysis circuitry 214 may be instantiated by any other combination of hardware, software, and/or firmware. For example, the model analysis circuitry 214 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the camera calibration circuitry 102 includes means for communicating. For example, the means for communicating may be implemented by the communication circuitry 216. In some examples, the communication circuitry 216 may be instantiated by programmable circuitry such as the example programmable circuitry 1112 of FIG. 11. For instance, the communication circuitry 216 may be instantiated by the example microprocessor 1200 of FIG. 12 executing machine executable instructions such as those implemented by at least block 820 of FIG. 8. In some examples, the communication circuitry 216 may be instantiated by hardware logic circuitry, which may be implemented by an ASIC, XPU, or the FPGA circuitry 1300 of FIG. 13 configured and/or structured to perform operations corresponding to the machine readable instructions. Additionally or alternatively, the communication circuitry 216 may be instantiated by any other combination of hardware, software, and/or firmware. For example, the communication circuitry 216 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the camera calibration circuitry 102 of FIG. 1 is illustrated in FIG. 2, one or more of the elements, processes, and/or devices illustrated in FIG. 2 may be combined, divided, re-arranged, omitted, eliminated, and/or implemented in any other way. Further, the example input interface circuitry 202, the example point cloud generation circuitry 204, the example plane fitting circuitry 206, the example transformation circuitry 208, the example feature tracking circuitry 210, the example yaw estimation circuitry 212, the example model analysis circuitry 214, the example communication circuitry 216, and/or, more generally, the example camera calibration circuitry 102 of FIG. 2, may be implemented by hardware alone or by hardware in combination with software and/or firmware. Thus, for example, any of the example input interface circuitry 202, the example point cloud generation circuitry 204, the example plane fitting circuitry 206, the example transformation circuitry 208, the example feature tracking circuitry 210, the example yaw estimation circuitry 212, the example model analysis circuitry 214, the example communication circuitry 216, and/or, more generally, the example camera calibration circuitry 102, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example camera calibration circuitry 102 of FIG. 2 may include one or more elements, processes, and/or devices in addition to, or instead of, those illustrated in FIG. 2, and/or may include more than one of any or all of the illustrated elements, processes and devices.

Flowchart(s) representative of example machine readable instructions, which may be executed by programmable circuitry to implement and/or instantiate the camera calibration circuitry 102 of FIG. 2 and/or representative of example operations which may be performed by programmable circuitry to implement and/or instantiate the camera calibration circuitry 102 of FIG. 2, are shown in FIGS. 8, 9, and/or 10. The machine readable instructions may be one or more executable programs or portion(s) of one or more executable programs for execution by programmable circuitry such as the processor circuitry 1112 shown in the example processor platform 1100 discussed below in connection with FIG. 11 and/or may be one or more function(s) or portion(s) of functions to be performed by the example programmable circuitry (e.g., an FPGA) discussed below in connection with FIGS. 12 and/or 13. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 8, 9, and/or 10, many other methods of implementing the example camera calibration circuitry 102 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 8, 9, and/or 10 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 8 is a flowchart representative of example machine readable instructions and/or example operations 800 that may be executed, instantiated, and/or performed by programmable circuitry to implement the example camera calibration circuitry 102 of FIGS. 1 and/or 2. The example machine-readable instructions and/or the example operations 800 of FIG. 8 begin at block 802, at which the example camera calibration circuitry 102 accesses example video frames captured by the first example camera 104 of FIG. 1. For example, the example input interface circuitry 202 obtains one or more first video frames (e.g., first images) from a first camera sensor of the first camera 104, and/or obtains one or more second video frames (e.g., second images) from a second camera sensor of the first camera 104.

At block 804, the example camera calibration circuitry 102 generates point cloud data corresponding to one(s) of the video frames. For example, the example point cloud generation circuitry 204 of FIG. 2 generates a disparity image based on calculated distances (e.g., 2-D distances) between corresponding points in the first and second video frames and generates point cloud data based on the disparity image. In some examples, the disparity image indicates depth values associated with each pixel in the disparity image, where the depth values represent 3-D distances between the first camera 104 and 3-D points represented by the corresponding pixels. In some examples, the point cloud generation circuitry 204 determines the depth values based on focal lengths of the first and second camera sensors of the first camera 104 and based on the calculated distances between the corresponding points in the first and second video frames. In some examples, the point cloud data generated based on one(s) of the disparity image includes 3-D coordinates (e.g., x-axis coordinates, y-axis coordinates, and z-axis coordinates) of one or more features represented in the video frames, where the 3-D coordinates are relative to the first camera coordinate system 112 of the first camera 104.

At block 806, the example camera calibration circuitry 102 selects an example ground plane based on the example point cloud data. For example, the example plane fitting circuitry 206 of FIG. 2 executes a RANSAC algorithm based on the point cloud data to determine the ground plane on which the vehicle 100 is positioned. In some examples, the plane fitting circuitry 206 iteratively selects candidate ground planes and calculates error values based on distances between the ground planes and a subset of data points of the point cloud data. In such examples, the plane fitting circuitry 206 selects the ground plane corresponding to the candidate ground plane that satisfies the error value. In some examples, the ground plane is represented as a vector normal to the ground plane (e.g., a ground plane normal).

At block 808, the example camera calibration circuitry 102 determines a roll angle, a pitch angle, and/or an x-axis coordinate based on the ground plane. For example, the example transformation circuitry 208 of FIG. 2 determines the roll angle, the pitch angle, and/or the x-axis coordinate of the first camera 104 relative to the example vehicle coordinate system 128 of the vehicle 100 based on the ground plane. Determination of the roll angle, the pitch angle, and/or the x-axis coordinate is described further below in connection with the flowchart in FIG. 9.

At block 810, the example camera calibration circuitry 102 determines whether the example vehicle 100 of FIG. 1 is moving. For example, the input interface circuitry 202 obtains example sensor data 224 from the one or more example vehicle sensors 110 of FIG. 1. In some examples, the sensor data 224 includes GPS data representing a geographic location of the vehicle 100. In some examples, the input interface circuitry 202 determines whether the vehicle 100 is moving based on whether the GPS data indicates that the geographic location of the vehicle 100 is changing. In response to the input interface circuitry 202 determining that the vehicle 100 is not moving (e.g., block 810 returns a result of NO), control returns to block 810. Alternatively, in response to the input interface circuitry 202 determining that the vehicle 100 is moving (e.g., block 810 returns a result of YES), control proceeds to block 812.

At block 812, the example camera calibration circuitry 102 tracks one or more features between ones of the video frames. For example, the example feature tracking circuitry 210 of FIG. 2 detects, based on execution of one or more image processing algorithms and/or one or more neural network models, the features in ones of the video frames corresponding to different times. In some examples, the features include objects (e.g., rocks, protrusions, edges, etc.) and/or textures of a 3-D scene represented in the video frames. In some examples, the feature tracking circuitry 210 tracks locations of corresponding ones of the features in two or more subsequent video frames.

At block 814, the example camera calibration circuitry 102 determines whether the tracked features satisfy one or more thresholds. For example, the feature tracking circuitry 210 determines whether at least a threshold number (e.g., three, ten, etc.) of features have been tracked, and/or whether the features have been tracked across a threshold number (e.g., five, ten, etc.) of subsequent ones of the video frames. In response to the feature tracking circuitry 210 determining that the tracked features do not satisfy the one or more thresholds (e.g., block 814 returns a result of NO), control returns to block 812. Alternatively, in response to the feature tracking circuitry 210 determining that the tracked features satisfy the one or more thresholds (e.g., block 814 returns a results of YES), control proceeds to block 816.

At block 816, the example camera calibration circuitry 102 determines a yaw angle based on the tracked features. For example, the example yaw estimation circuitry 212 of FIG. 2 determines, by executing a coherent point drift algorithm based on the tracked features, an example camera path of the first camera 104. In some examples, the yaw estimation circuitry 212 determines an example vehicle path of the vehicle 100 based on GPS data obtained by the input interface circuitry 202. In some examples, the yaw estimation circuitry 212 determines the yaw angle based on a comparison of the camera path and the vehicle path. Determination of the yaw angle is described further below in connection with the flowchart in FIG. 10.

At block 818, the example camera calibration circuitry 102 determines an x-axis coordinate (e.g., an x-axis translation) and/or a y-axis coordinate (e.g., a y-axis translation) based on an example vehicle model. For example, the example model analysis circuitry 214 of FIG. 2 determines the x-axis coordinate and/or the y-axis coordinate of the first camera coordinate system 112 relative to the vehicle coordinate system 128 of FIG. 1. In some examples, the model analysis circuitry 214 determines the x-axis coordinate and/or the y-axis coordinate based on a vehicle model (e.g., a vehicle CAD model) of the vehicle 100 obtained and/or stored by the camera calibration circuitry 102.

At block 820, the example camera calibration circuitry 102 stores the calibration results. For example, the transformation circuitry 208 causes storage of the roll angle, the pitch angle, and/or the z-axis coordinate in the example database 218 of FIG. 2. In some examples, the yaw estimation circuitry 212 causes storage of the yaw angle in the database 218. In some examples, the model analysis circuitry 214 causes storage of the x-axis coordinate and/or the y-axis coordinate in the database 218. In some examples, the example communication circuitry 216 provides, via the example network 108 of FIG. 1, the calibration results (e.g., the yaw angle, the roll angle, the pitch angle, the x-axis coordinate, the y-axis coordinate, and/or the z-axis coordinate) to a cloud-based storage location and/or to another storage location communicatively coupled to the camera calibration circuitry 102.

At block 822, the example camera calibration circuitry 102 determines whether calibration is complete. For example, the transformation circuitry 208, the yaw estimation circuitry 212, and/or the model analysis circuitry 214 determines whether the each of the calibration results (e.g., the yaw angle, the roll angle, the pitch angle, the x-axis coordinate, the y-axis coordinate, and the z-axis coordinate) have been determined. In response to the calibration not being complete (e.g., block 822 returns a result of NO), control returns to block 802. Alternatively, in response to the calibration being complete (e.g., block 822 returns a result of YES), control ends.

FIG. 9 is a flowchart representative of example machine readable instructions and/or example operations 900 that may be executed, instantiated, and/or performed by programmable circuitry to determine an example roll angle, an example pitch angle, and/or an example roll angle in connection with block 808 of FIG. 8. The example machine-readable instructions and/or the example operations 900 of FIG. 9 begin at block 902, at which the example camera calibration circuitry 102 of FIGS. 1 and/or 2 determines a relative transformation between the first camera sensor and the second camera sensor of the first example camera 104 of FIG. 1. For example, the example transformation circuitry 208 of FIG. 2 obtains, from the example plane fitting circuitry 206 of FIG. 2, a first ground plane normal (e.g., ¹n) representing the ground plane in a first coordinate system of the first camera sensor and a second ground plane normal (e.g., ²n) representing the ground plane in a second coordinate system of the second camera sensor. In some examples, the transformation circuitry 208 determines, based on the first and second ground plane normal and a cost function represented in example Equation 6 above, values for a camera-to-camera rotation matrix (e.g., ¹R₂) and a camera-to-camera translation vector (e.g., ¹t₂). In some examples, based on the camera-to-camera rotation matrix and the camera-to-camera translation vector, the transformation circuitry 208 can map (e.g., convert, transform) points and/or features in the second coordinate system of the second camera sensor to corresponding points and/or features in the first coordinate system of the first camera sensor.

At block 904, the example camera calibration circuitry 102 selects a ground plane normal (e.g., ^{S}n) representing the ground plane in the vehicle coordinate system 128 of FIG. 1. For example, the transformation circuitry 208 selects the ground plane normal in the vehicle coordinate system 128 corresponding to the vehicle z-axis 134 of FIG. 1.

At block 906, the example camera calibration circuitry 102 determines an example vehicle-to-camera rotation matrix (e.g., ^{C}R_{S}) based on the ground plane normals in the first camera coordinate system 112 and the vehicle coordinate system 128. For example, the transformation circuitry determines, based on the ground plane normals in the first camera coordinate system 112 and the vehicle coordinate system 128 and the cost function in example Equation 10 above, the vehicle-to-camera rotation matrix. In some examples, the transformation circuitry 208 iteratively selects candidate values for the vehicle-to-camera rotation matrix and selects the candidate values that satisfy an error threshold as actual values for the vehicle-to-camera rotation matrix.

At block 908, the example camera calibration circuitry 102 determines the roll angle and/or the pitch angle based on the vehicle-to-camera rotation matrix. For example, the transformation circuitry 208 determines the roll angle and the pitch angle based on angles of rotation of the first camera coordinate system 112 about the first camera x-axis 114 and the first camera y-axis 116, respectively, to align the camera ground plane normal with the first camera z-axis 118 of the first camera coordinate system 112.

At block 910, the example camera calibration circuitry 102 determines the z-axis coordinate corresponding to a distance between the ground plane and an origin of the first camera coordinate system 112. For example, the transformation circuitry 208 determines the z-axis coordinate of the first camera coordinate system 112 relative to the vehicle coordinate system 120 based on the distance between the ground plane and an origin of the first camera coordinate system 112.

FIG. 10 is a flowchart representative of example machine readable instructions and/or example operations 1000 that may be executed, instantiated, and/or performed by programmable circuitry to determine an example yaw angle in connection with block 816 of FIG. 8. The example machine-readable instructions and/or the example operations 1000 of FIG. 10 begin at block 1002, at which the example camera calibration circuitry 102 of FIGS. 1 and/or 2 obtains example point cloud data (e.g., the first and second example point clouds 602, 604 of FIGS. 6A and/or 6B) corresponding to first and second video frames captured by the example camera 104 of FIG. 1. For example, the example yaw estimation circuitry 212 of FIG. 2 obtains the first and second point clouds 602, 604 generated by the feature tracking circuitry 210 based on the tracking of features in the first and second video frames.

At block 1004, the example camera calibration circuitry 102 identifies first tracked features in the first point cloud 602 corresponding to second tracked features in the second point cloud 604. For example, the example yaw estimation circuitry 212 identifies correspondences between the first tracked features and the second tracked features, where the corresponding first and second tracked features correspond to a same location in a 3-D space surrounding the example vehicle 100 of FIG. 1.

At block 1006, the example camera calibration circuitry 102 determines a transformation that maps the first tracked features to the corresponding second tracked features. For example, the yaw estimation circuitry 212 utilizes a coherent point drift algorithm to determine the transformation (e.g., rotation and/or translation) based on the first and second point clouds 602, 604. In some examples, the transformation indicates an amount of translation and/or rotation of the first point cloud 602 along a 2-D plane (e.g., the plane defined by the axes 606, 608 of FIGS. 6A and/or 6B) to map the first point cloud 602 onto the second point cloud 604. In some examples, a different technique (e.g., least squares regression) can be used to determine the transformation.

At block 1008, the example camera calibration circuitry 102 determines the example camera path 702 of FIG. 7 based on the transformation. For example, the yaw estimation circuitry 212 determines the camera path 702 based on an aggregation of transformations determined between different ones of the video frames from the first camera 104 captured at different times. In some examples, the camera path 702 indicates rotations and/or translations of the first camera 104 during a duration for which the vehicle 100 traverses the example vehicle path 712 of FIG. 7 (e.g., a substantially straight path).

At block 1010, the example camera calibration circuitry 102 determines the example vehicle path 712 based on the example sensor data 224 from the one or more example vehicle sensors 110 of FIG. 1. For example, the yaw estimation circuitry 212 determines the vehicle path 712 based on GPS data from the vehicle sensor(s) 110. In this example, the vehicle path 712 is a substantially straight line (e.g., aligned with the example x-axis 704 of FIG. 7). In some examples, the vehicle path 712 can be different (e.g., curved).

At block 1012, the example camera calibration circuitry 102 determines the yaw angle based on a comparison between the camera path 702 and the vehicle path 712. For example, the yaw estimation circuitry 212 determines the yaw angle corresponding to an angle of rotation of the camera path 702 about the example z-axis 708 of FIG. 7 that aligns (e.g., substantially aligns) the camera path 702 with the vehicle path 712. In some examples, the yaw angle corresponds to an angle of rotation of the first camera coordinate system 112 of FIG. 1 about the vehicle z-axis 134 of the vehicle coordinate system 128 of FIG. 1 that aligns (e.g., substantially aligns) the first camera x-axis 114 of the first camera coordinate system 112 to the vehicle x-axis 130 of the vehicle coordinate system 128.

FIG. 11 is a block diagram of an example programmable circuitry platform 1100 structured to execute and/or instantiate the example machine-readable instructions and/or the example operations of FIGS. 8, 9, and/or 10 to implement the camera calibration circuitry 102 of FIG. 2. The programmable circuitry platform 1100 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1100 of the illustrated example includes programmable circuitry 1112. The programmable circuitry 1112 of the illustrated example is hardware. For example, the programmable circuitry 1112 can be implemented by one or more integrated circuits, logic circuits, FPGAs, microprocessors, CPUs, GPUs, DSPs, and/or microcontrollers from any desired family or manufacturer. The programmable circuitry 1112 may be implemented by one or more semiconductor based (e.g., silicon based) devices. In this example, the programmable circuitry 1112 implements example input interface circuitry 202, the example point cloud generation circuitry 204, the example plane fitting circuitry 206, the example transformation circuitry 208, the example feature tracking circuitry 210, the example yaw estimation circuitry 212, the example model analysis circuitry 214, and/or the example communication circuitry 216.

The programmable circuitry 1112 of the illustrated example includes a local memory 1113 (e.g., a cache, registers, etc.). The programmable circuitry 1112 of the illustrated example is in communication with main memory 1114, 1116, which includes a volatile memory 1114 and a non-volatile memory 1116, by a bus 1118. The volatile memory 1114 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1116 may be implemented by flash memory and/or any other desired type of memory device. Access to the main memory 1114, 1116 of the illustrated example is controlled by a memory controller 1117. In some examples, the memory controller 1117 may be implemented by one or more integrated circuits, logic circuits, microcontrollers from any desired family or manufacturer, or any other type of circuitry to manage the flow of data going to and from the main memory 1114, 1116.

The programmable circuitry platform 1100 of the illustrated example also includes interface circuitry 1120. The interface circuitry 1120 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1122 are connected to the interface circuitry 1120. The input device(s) 1122 permit(s) a user (e.g., a human user, a machine user, etc.) to enter data and/or commands into the programmable circuitry 1112. The input device(s) 1122 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1124 are also connected to the interface circuitry 1120 of the illustrated example. The output device(s) 1124 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1120 of the illustrated example, thus, typically includes a graphics driver card, a graphics driver chip, and/or graphics processor circuitry such as a GPU.

The interface circuitry 1120 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1126. The communication can be by, for example, an Ethernet connection, a digital subscriber line (DSL) connection, a telephone line connection, a coaxial cable system, a satellite system, a beyond-line-of-site wireless system, a line-of-site wireless system, a cellular telephone system, an optical connection, etc.

The programmable circuitry platform 1100 of the illustrated example also includes one or more mass storage discs or devices 1128 to store firmware, software, and/or data. Examples of such mass storage discs or devices 1128 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1132, which may be implemented by the machine readable instructions of FIGS. 8, 9, and/or 10, may be stored in the mass storage device 1128, in the volatile memory 1114, in the non-volatile memory 1116, and/or on at least one non-transitory computer readable storage medium such as a CD or DVD which may be removable.

FIG. 12 is a block diagram of an example implementation of the programmable circuitry 1112 of FIG. 11. In this example, the programmable circuitry 1112 of FIG. 11 is implemented by a microprocessor 1200. For example, the microprocessor 1200 may be a general-purpose microprocessor (e.g., general-purpose microprocessor circuitry). The microprocessor 1200 executes some or all of the machine-readable instructions of the flowcharts of FIGS. 8, 9, and/or 10 to effectively instantiate the circuitry of FIG. 2 as logic circuits to perform operations corresponding to those machine readable instructions. In some such examples, the circuitry of FIG. 2 is instantiated by the hardware circuits of the microprocessor 1200 in combination with the machine-readable instructions. For example, the microprocessor 1200 may be implemented by multi-core hardware circuitry such as a CPU, a DSP, a GPU, an XPU, etc. Although it may include any number of example cores 1202 (e.g., 1 core), the microprocessor 1200 of this example is a multi-core semiconductor device including N cores. The cores 1202 of the microprocessor 1200 may operate independently or may cooperate to execute machine readable instructions. For example, machine code corresponding to a firmware program, an embedded software program, or a software program may be executed by one of the cores 1202 or may be executed by multiple ones of the cores 1202 at the same or different times. In some examples, the machine code corresponding to the firmware program, the embedded software program, or the software program is split into threads and executed in parallel by two or more of the cores 1202. The software program may correspond to a portion or all of the machine readable instructions and/or operations represented by the flowcharts of FIGS. 8, 9, and/or 10.

The cores 1202 may communicate by a first example bus 1204. In some examples, the first bus 1204 may be implemented by a communication bus to effectuate communication associated with one(s) of the cores 1202. For example, the first bus 1204 may be implemented by at least one of an Inter-Integrated Circuit (I2C) bus, a Serial Peripheral Interface (SPI) bus, a PCI bus, or a PCIe bus. Additionally or alternatively, the first bus 1204 may be implemented by any other type of computing or electrical bus. The cores 1202 may obtain data, instructions, and/or signals from one or more external devices by example interface circuitry 1206. The cores 1202 may output data, instructions, and/or signals to the one or more external devices by the interface circuitry 1206. Although the cores 1202 of this example include example local memory 1220 (e.g., Level 1 (L1) cache that may be split into an L1 data cache and an L1 instruction cache), the microprocessor 1200 also includes example shared memory 1210 that may be shared by the cores (e.g., Level 2 (L2 cache)) for high-speed access to data and/or instructions. Data and/or instructions may be transferred (e.g., shared) by writing to and/or reading from the shared memory 1210. The local memory 1220 of each of the cores 1202 and the shared memory 1210 may be part of a hierarchy of storage devices including multiple levels of cache memory and the main memory (e.g., the main memory 1114, 1116 of FIG. 11). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1202 may be referred to as a CPU, DSP, GPU, etc., or any other type of hardware circuitry. Each core 1202 includes control unit circuitry 1214, arithmetic and logic (AL) circuitry (sometimes referred to as an ALU) 1216, a plurality of registers 1218, the local memory 1220, and a second example bus 1222. Other structures may be present. For example, each core 1202 may include vector unit circuitry, single instruction multiple data (SIMD) unit circuitry, load/store unit (LSU) circuitry, branch/jump unit circuitry, floating-point unit (FPU) circuitry, etc. The control unit circuitry 1214 includes semiconductor-based circuits structured to control (e.g., coordinate) data movement within the corresponding core 1202. The AL circuitry 1216 includes semiconductor-based circuits structured to perform one or more mathematic and/or logic operations on the data within the corresponding core 1202. The AL circuitry 1216 of some examples performs integer based operations. In other examples, the AL circuitry 1216 also performs floating-point operations. In yet other examples, the AL circuitry 1216 may include first AL circuitry that performs integer-based operations and second AL circuitry that performs floating-point operations. In some examples, the AL circuitry 1216 may be referred to as an Arithmetic Logic Unit (ALU).

The registers 1218 are semiconductor-based structures to store data and/or instructions such as results of one or more of the operations performed by the AL circuitry 1216 of the corresponding core 1202. For example, the registers 1218 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1218 may be arranged in a bank as shown in FIG. 12. Alternatively, the registers 1218 may be organized in any other arrangement, format, or structure, such as by being distributed throughout the core 1202 to shorten access time. The second bus 1222 may be implemented by at least one of an I2C bus, a SPI bus, a PCI bus, or a PCIe bus.

Each core 1202 and/or, more generally, the microprocessor 1200 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1200 is a semiconductor device fabricated to include many transistors interconnected to implement the structures described above in one or more integrated circuits (ICs) contained in one or more packages.

The microprocessor 1200 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1200, in the same chip package as the microprocessor 1200 and/or in one or more separate packages from the microprocessor 1200.

FIG. 13 is a block diagram of another example implementation of the programmable circuitry 1112 of FIG. 11. In this example, the programmable circuitry 1112 is implemented by FPGA circuitry 1300. For example, the FPGA circuitry 1300 may be implemented by an FPGA. The FPGA circuitry 1300 can be used, for example, to perform operations that could otherwise be performed by the example microprocessor 1200 of FIG. 12 executing corresponding machine readable instructions. However, once configured, the FPGA circuitry 1300 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1200 of FIG. 12 described above (which is a general purpose device that may be programmed to execute some or all of the machine readable instructions represented by the flowchart(s) of FIGS. 8, 9, and/or 10 but whose interconnections and logic circuitry are fixed once fabricated), the FPGA circuitry 1300 of the example of FIG. 13 includes interconnections and logic circuitry that may be configured, structured, programmed, and/or interconnected in different ways after fabrication to instantiate, for example, some or all of the operations/functions corresponding to the machine readable instructions represented by the flowchart(s) of FIGS. 8, 9, and/or 10. In particular, the FPGA circuitry 1300 may be thought of as an array of logic gates, interconnections, and switches. The switches can be programmed to change how the logic gates are interconnected by the interconnections, effectively forming one or more dedicated logic circuits (unless and until the FPGA circuitry 1300 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 8, 9, and/or 10. As such, the FPGA circuitry 1300 may be configured and/or structured to effectively instantiate some or all of the operations/functions corresponding to the machine readable instructions of the flowchart(s) of FIGS. 8, 9, and/or 10 as dedicated logic circuits to perform the operations/functions corresponding to those software instructions in a dedicated manner analogous to an ASIC. Therefore, the FPGA circuitry 1300 may perform the operations/functions corresponding to the some or all of the machine readable instructions of FIGS. 8, 9, and/or 10 faster than the general-purpose microprocessor can execute the same.

In the example of FIG. 13, the FPGA circuitry 1300 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1300 of FIG. 13 may access and/or load the binary file to cause the FPGA circuitry 1300 of FIG. 13 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1300 of FIG. 13 to cause configuration and/or structuring of the FPGA circuitry 1300 of FIG. 13, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1300 of FIG. 13 may access and/or load the binary file to cause the FPGA circuitry 1300 of FIG. 13 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1300 of FIG. 13 to cause configuration and/or structuring of the FPGA circuitry 1300 of FIG. 13, or portion(s) thereof.

The FPGA circuitry 1300 of FIG. 13, includes example input/output (I/O) circuitry 1302 to obtain and/or output data to/from example configuration circuitry 1304 and/or external hardware 1306. For example, the configuration circuitry 1304 may be implemented by interface circuitry that may obtain a binary file, which may be implemented by a bit stream, data, and/or machine-readable instructions, to configure the FPGA circuitry 1300, or portion(s) thereof. In some such examples, the configuration circuitry 1304 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1306 may be implemented by external hardware circuitry. For example, the external hardware 1306 may be implemented by the microprocessor 1200 of FIG. 12.

The FPGA circuitry 1300 also includes an array of example logic gate circuitry 1308, a plurality of example configurable interconnections 1310, and example storage circuitry 1312. The logic gate circuitry 1308 and the configurable interconnections 1310 are configurable to instantiate one or more operations/functions that may correspond to at least some of the machine readable instructions of FIGS. 8, 9, and/or 10 and/or other desired operations. The logic gate circuitry 1308 shown in FIG. 13 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1308 to enable configuration of the electrical structures and/or the logic gates to form circuits to perform desired operations/functions. The logic gate circuitry 1308 may include other electrical structures such as look-up tables (LUTs), registers (e.g., flip-flops or latches), multiplexers, etc.

The configurable interconnections 1310 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1308 to program desired logic circuits.

The storage circuitry 1312 of the illustrated example is structured to store result(s) of the one or more of the operations performed by corresponding logic gates. The storage circuitry 1312 may be implemented by registers or the like. In the illustrated example, the storage circuitry 1312 is distributed amongst the logic gate circuitry 1308 to facilitate access and increase execution speed.

The example FPGA circuitry 1300 of FIG. 13 also includes example dedicated operations circuitry 1314. In this example, the dedicated operations circuitry 1314 includes special purpose circuitry 1316 that may be invoked to implement commonly used functions to avoid the need to program those functions in the field. Examples of such special purpose circuitry 1316 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1300 may also include example general purpose programmable circuitry 1318 such as an example CPU 1320 and/or an example DSP 1322. Other general purpose programmable circuitry 1318 may additionally or alternatively be present such as a GPU, an XPU, etc., that can be programmed to perform other operations.

Although FIGS. 12 and 13 illustrate two example implementations of the programmable circuitry 1112 of FIG. 11, many other approaches are contemplated. For example, FPGA circuitry may include an on-board CPU, such as one or more of the example CPU 1320 of FIG. 12. Therefore, the programmable circuitry 1112 of FIG. 11 may additionally be implemented by combining at least the example microprocessor 1200 of FIG. 12 and the example FPGA circuitry 1300 of FIG. 13. In some such hybrid examples, one or more cores 1202 of FIG. 12 may execute a first portion of the machine readable instructions represented by the flowchart(s) of FIGS. 8, 9, and/or 10 to perform first operation(s)/function(s), the FPGA circuitry 1300 of FIG. 13 may be configured and/or structured to perform second operation(s)/function(s) corresponding to a second portion of the machine readable instructions represented by the flowcharts of FIGS. 8, 9, and/or 10, and/or an ASIC may be configured and/or structured to perform third operation(s)/function(s) corresponding to a third portion of the machine readable instructions represented by the flowcharts of FIGS. 8, 9, and/or 10.

It should be understood that some or all of the circuitry of FIG. 2 may, thus, be instantiated at the same or different times. For example, same and/or different portion(s) of the microprocessor 1200 of FIG. 12 may be programmed to execute portion(s) of machine-readable instructions at the same and/or different times. In some examples, same and/or different portion(s) of the FPGA circuitry 1300 of FIG. 13 may be configured and/or structured to perform operations/functions corresponding to portion(s) of machine-readable instructions at the same and/or different times.

In some examples, some or all of the circuitry of FIG. 2 may be instantiated, for example, in one or more threads executing concurrently and/or in series. For example, the microprocessor 1200 of FIG. 12 may execute machine readable instructions in one or more threads executing concurrently and/or in series. In some examples, the FPGA circuitry 1300 of FIG. 13 may be configured and/or structured to carry out operations/functions concurrently and/or in series. Moreover, in some examples, some or all of the circuitry of FIG. 2 may be implemented within one or more virtual machines and/or containers executing on the microprocessor 1200 of FIG. 12.

In some examples, the programmable circuitry 1112 of FIG. 11 may be in one or more packages. For example, the microprocessor 1200 of FIG. 12 and/or the FPGA circuitry 1300 of FIG. 13 may be in one or more packages. In some examples, an XPU may be implemented by the programmable circuitry 1112 of FIG. 11, which may be in one or more packages. For example, the XPU may include a CPU (e.g., the microprocessor 1200 of FIG. 12, the CPU 1320 of FIG. 13, etc.) in one package, a DSP (e.g., the DSP 1322 of FIG. 13) in another package, a GPU in yet another package, and an FPGA (e.g., the FPGA circuitry 1300 of FIG. 13) in still yet another package.

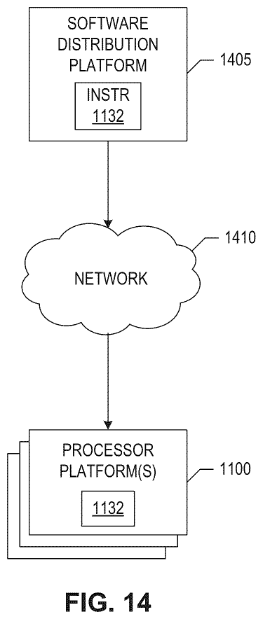

A block diagram illustrating an example software distribution platform 1405 to distribute software such as the example machine readable instructions 1132 of FIG. 11 to other hardware devices (e.g., hardware devices owned and/or operated by third parties from the owner and/or operator of the software distribution platform) is illustrated in FIG. 14. The example software distribution platform 1405 may be implemented by any computer server, data facility, cloud service, etc., capable of storing and transmitting software to other computing devices. The third parties may be customers of the entity owning and/or operating the software distribution platform 1405. For example, the entity that owns and/or operates the software distribution platform 1405 may be a developer, a seller, and/or a licensor of software such as the example machine readable instructions 1132 of FIG. 11. The third parties may be consumers, users, retailers, OEMs, etc., who purchase and/or license the software for use and/or re-sale and/or sub-licensing. In the illustrated example, the software distribution platform 1405 includes one or more servers and one or more storage devices. The storage devices store the machine readable instructions 1132, which may correspond to the example machine readable instructions of FIGS. 8, 9, and/or 10, as described above. The one or more servers of the example software distribution platform 1405 are in communication with an example network 1410, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1132 from the software distribution platform 1405. For example, the software, which may correspond to the example machine readable instructions of FIGS. 8, 9, and/or 10, may be downloaded to the example programmable circuitry platform 1100, which is to execute the machine readable instructions 1132 to implement the camera calibration circuitry 102. In some examples, one or more servers of the software distribution platform 1405 periodically offer, transmit, and/or force updates to the software (e.g., the example machine readable instructions 1132 of FIG. 11) to ensure improvements, patches, updates, etc., are distributed and applied to the software at the end user devices. Although referred to as software above, the distributed “software” could alternatively be firmware.

From the foregoing, it will be appreciated that example systems, apparatus, articles of manufacture, and methods have been disclosed that calibrate an example camera relative to an example vehicle coordinate system of an example vehicle. Examples disclosed herein detect a ground plane of the vehicle based on one or more first video frames captured by the camera when the vehicle is stationary and determine first calibration parameter(s) (e.g., roll angle, pitch angle, and/or z-axis coordinate) based on the ground plane. Further, examples disclosed herein track features between corresponding second video frames captured by the camera when the vehicle is moving and determine second calibration parameter(s) (e.g., yaw angle) based on the tracked features. Disclosed systems, apparatus, articles of manufacture, and methods improve the efficiency of using a computing device by performing calibration of a camera without the use of fiducial markers, thus reducing inaccuracy in the calibration resulting from inaccurate and/or improper placement of the fiducial markers with respect to the vehicle. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture for camera calibration are disclosed herein. Further examples and combinations thereof include the following:

Example 1 includes an apparatus comprising memory, instructions, an interface to receive video frames captured by a camera positioned on a vehicle, and programmable circuitry coupled to the interface, wherein the programmable circuitry is to execute the instructions to at least detect, based on the video frames, a ground plane of the vehicle, determine, based on the ground plane, a first position parameter of the camera with respect to a coordinate system of the vehicle, track a plurality of features between ones of the video frames, and determine, based on the plurality of features, a second position parameter of the camera with respect to the coordinate system of the vehicle, the first position parameter different from the second position parameter.

Example 2 includes the apparatus of example 1, wherein the first position parameter includes at least one of a roll angle, a pitch angle, or a z-axis coordinate of the camera with respect to the coordinate system of the vehicle.

Example 3 includes the apparatus of example 1, wherein the second position parameter includes a yaw angle of the camera with respect to the coordinate system of the vehicle.

Example 4 includes the apparatus of example 1, wherein the programmable circuitry is to execute the instructions to determine at least one of an x-axis coordinate or a y-axis coordinate of the camera with respect to the coordinate system of the vehicle based on a computer-aided design (CAD) model of the vehicle.

Example 5 includes the apparatus of example 1, wherein the programmable circuitry is to execute the instructions to access point cloud data corresponding to at least one of the video frames and detect the ground plane by executing a random sampling and consensus (RANSAC) algorithm based on the point cloud data.

Example 6 includes the apparatus of example 1, wherein the programmable circuitry is to estimate a camera path of the camera based on the plurality of features and determine the second position parameter by comparing the camera path to a vehicle path of the vehicle.

Example 7 includes the apparatus of example 6, wherein the programmable circuitry is to execute the instructions to estimate the camera path in response to a count of the plurality of features satisfying a threshold.

Example 8 includes the apparatus of example 1, wherein the programmable circuitry is to execute the instructions to track the plurality of features in response to determining that the vehicle is moving.

Example 9 includes the apparatus of example 1, wherein the programmable circuitry is to execute the instructions to detect the ground plane when the vehicle is stationary.

Example 10 includes a non-transitory computer readable medium comprising instructions that, when executed, cause programmable circuitry to at least detect, based on video frames captured by a camera positioned on a vehicle, a ground plane of the vehicle, determine, based on the ground plane, a first position parameter of the camera with respect to a coordinate system of the vehicle, track a plurality of features between ones of the video frames, and determine, based on the plurality of features, a second position parameter of the camera with respect to the coordinate system of the vehicle, the first position parameter different from the second position parameter.

Example 11 includes the non-transitory computer readable medium of example 10, wherein the first position parameter includes at least one of a roll angle, a pitch angle, or a z-axis coordinate of the camera with respect to the coordinate system of the vehicle.

Example 12 includes the non-transitory computer readable medium of example 10, wherein the second position parameter includes a yaw angle of the camera with respect to the coordinate system of the vehicle.

Example 13 includes the non-transitory computer readable medium of example 10, wherein the instructions, when executed, cause the programmable circuitry to determine at least one of an x-axis coordinate or a y-axis coordinate of the camera with respect to the coordinate system of the vehicle based on a computer-aided design (CAD) model of the vehicle.

Example 14 includes an apparatus comprising plane fitting circuitry to detect, based on video frames captured by a camera positioned on a vehicle, a ground plane of the vehicle, transformation circuitry to determine, based on the ground plane, a first position parameter of the camera with respect to a coordinate system of the vehicle, feature tracking circuitry to track a plurality of features between ones of the video frames, and yaw estimation circuitry to determine, based on the plurality of features, a second position parameter of the camera with respect to the coordinate system of the vehicle, the first position parameter different from the second position parameter.

Example 15 includes the apparatus of example 14, wherein the plane fitting circuitry is to access point cloud data corresponding to at least one of the video frames and detect the ground plane by executing a random sampling and consensus (RANSAC) algorithm based on the point cloud data.

Example 16 includes the apparatus of example 14, wherein the yaw estimation circuitry is to estimate a camera path of the camera based on the plurality of features and determine the second position parameter by comparing the camera path to a vehicle path of the vehicle.

Example 17 includes the apparatus of example 16, wherein the yaw estimation circuitry is to estimate the camera path in response to a count of the plurality of features satisfying a threshold.

Example 18 includes the apparatus of example 16, wherein the second position parameter includes a yaw angle of the camera with respect to the coordinate system of the vehicle.

Example 19 includes the apparatus of example 14, wherein the first position parameter includes at least one of a roll angle, a pitch angle, or a z-axis coordinate of the camera with respect to the coordinate system of the vehicle.

Example 20 includes the apparatus of example 14, further including model analysis circuitry to determine at least one of an x-axis coordinate or a y-axis coordinate of the camera with respect to the coordinate system of the vehicle based on a computer-aided design (CAD) model of the vehicle.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
memory;
instructions;
an interface to receive video frames captured by a camera positioned on a vehicle; and
programmable circuitry coupled to the interface, wherein the programmable circuitry is to execute the instructions to at least:
detect, based on the video frames, a ground plane of the vehicle;
determine, based on the ground plane, a first position parameter of the camera with respect to a coordinate system of the vehicle;
track a plurality of features between ones of the video frames; and
determine, based on the plurality of features, a second position parameter of the camera with respect to the coordinate system of the vehicle, the first position parameter different from the second position parameter.

2. The apparatus of claim 1, wherein the first position parameter includes at least one of a roll angle, a pitch angle, or a z-axis coordinate of the camera with respect to the coordinate system of the vehicle.

3. The apparatus of claim 1, wherein the second position parameter includes a yaw angle of the camera with respect to the coordinate system of the vehicle.

4. The apparatus of claim 1, wherein the programmable circuitry is to execute the instructions to determine at least one of an x-axis coordinate or a y-axis coordinate of the camera with respect to the coordinate system of the vehicle based on a computer-aided design (CAD) model of the vehicle.

5. The apparatus of claim 1, wherein the programmable circuitry is to execute the instructions to:
access point cloud data corresponding to at least one of the video frames; and
detect the ground plane by executing a random sampling and consensus (RANSAC) algorithm based on the point cloud data.

6. The apparatus of claim 1, wherein the programmable circuitry is to:
estimate a camera path of the camera based on the plurality of features; and
determine the second position parameter by comparing the camera path to a vehicle path of the vehicle.

7. The apparatus of claim 6, wherein the programmable circuitry is to execute the instructions to estimate the camera path in response to a count of the plurality of features satisfying a threshold.

8. The apparatus of claim 1, wherein the programmable circuitry is to execute the instructions to track the plurality of features in response to determining that the vehicle is moving.

9. The apparatus of claim 1, wherein the programmable circuitry is to execute the instructions to detect the ground plane when the vehicle is stationary.

10. A non-transitory computer readable medium comprising instructions that, when executed, cause programmable circuitry to at least:
detect, based on video frames captured by a camera positioned on a vehicle, a ground plane of the vehicle;
determine, based on the ground plane, a first position parameter of the camera with respect to a coordinate system of the vehicle;
track a plurality of features between ones of the video frames; and
determine, based on the plurality of features, a second position parameter of the camera with respect to the coordinate system of the vehicle, the first position parameter different from the second position parameter.

11. The non-transitory computer readable medium of claim 10, wherein the first position parameter includes at least one of a roll angle, a pitch angle, or a z-axis coordinate of the camera with respect to the coordinate system of the vehicle.

12. The non-transitory computer readable medium of claim 10, wherein the second position parameter includes a yaw angle of the camera with respect to the coordinate system of the vehicle.

13. The non-transitory computer readable medium of claim 10, wherein the instructions, when executed, cause the programmable circuitry to determine at least one of an x-axis coordinate or a y-axis coordinate of the camera with respect to the coordinate system of the vehicle based on a computer-aided design (CAD) model of the vehicle.

14. An apparatus comprising:
plane fitting circuitry to detect, based on video frames captured by a camera positioned on a vehicle, a ground plane of the vehicle;
transformation circuitry to determine, based on the ground plane, a first position parameter of the camera with respect to a coordinate system of the vehicle;
feature tracking circuitry to track a plurality of features between ones of the video frames; and
yaw estimation circuitry to determine, based on the plurality of features, a second position parameter of the camera with respect to the coordinate system of the vehicle, the first position parameter different from the second position parameter.

15. The apparatus of claim 14, wherein the plane fitting circuitry is to:
access point cloud data corresponding to at least one of the video frames; and
detect the ground plane by executing a random sampling and consensus (RANSAC) algorithm based on the point cloud data.

16. The apparatus of claim 14, wherein the yaw estimation circuitry is to:
estimate a camera path of the camera based on the plurality of features; and
determine the second position parameter by comparing the camera path to a vehicle path of the vehicle.

17. The apparatus of claim 16, wherein the yaw estimation circuitry is to estimate the camera path in response to a count of the plurality of features satisfying a threshold.

18. The apparatus of claim 16, wherein the second position parameter includes a yaw angle of the camera with respect to the coordinate system of the vehicle.

19. The apparatus of claim 14, wherein the first position parameter includes at least one of a roll angle, a pitch angle, or a z-axis coordinate of the camera with respect to the coordinate system of the vehicle.

20. The apparatus of claim 14, further including model analysis circuitry to determine at least one of an x-axis coordinate or a y-axis coordinate of the camera with respect to the coordinate system of the vehicle based on a computer-aided design (CAD) model of the vehicle.
